(19) United States
(12) Patent Application Publication
(10) Pub. No.: US 2021/0066265 A1
(43) Pub. Date: Mar. 4, 2021

(54) TUNABLE CAPACITOR ARRANGEMENTS IN INTEGRATED CIRCUIT PACKAGE SUBSTRATES

(71) Applicant: Intel Corporation, Santa Clara, CA (US)

(72) Inventors: Feras Eid, Chandler, AZ (US); Aleksandar Aleksov, Chandler, AZ (US); Telesphor Kamgaing, Chandler, AZ (US); Georgios Dogiamis, Chandler, AZ (US); Johanna M. Swan, Scottsdale, AZ (US); Sivakumar Nagarajan, Chandler, AZ (US); Nitin A. Deshpande, Chandler, AZ (US); Omkar G. Karhade, Chandler, AZ (US); William James Lambert, Chandler, AZ (US)

(73) Assignee: Intel Corporation, Santa Clara, CA (US)

(21) Appl. No.: 16/553,544

(22) Filed: Aug. 28, 2019

(51) Int. Cl. H01L 25/16; H01L 23/13; H01L 23/498; H01L 23/00; H03F 3/213; H01G 2/06; H01G 2/10

(52) U.S. Cl. CPC H01L 25/16; H01L 23/3128; H01L 23/49838; H01L 24/16; H03F 3/213; H01G 2/06; H01G 2/10; H03F 2200/451; H01L 2224/16227; H01L 2224/32225; H01L 2224/73204; H01L 24/32; H01L 24/73; H01L 24/33; H01L 2224/33181; H01L 2224/32245; H01L 2224/73253; H01L 23/13

(57) ABSTRACT

Disclosed herein are tunable capacitor arrangements in integrated circuit (IC) package substrates, as well as related methods and devices. For example, in some embodiments, an IC package substrate may include a first embedded capacitor, a second embedded capacitor, and a fuse electrically coupled between the first embedded capacitor and the second embedded capacitor such that when the fuse is in a closed state, the first embedded capacitor and the second embedded capacitor are connected in parallel, and when the fuse is in an open state, the first embedded capacitor and the second embedded capacitor are not connected in parallel.

### BACKGROUND

Some integrated circuit (IC) packages include IC dies and additional passive components. Typically, such passive components are manufactured separately as discrete components and mounted to a surface of the package substrate.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 is a side, cross-sectional view of an integrated circuit (IC) assembly including an IC package with a tunable capacitor arrangement in a package substrate, in accordance with various embodiments.

FIG. 2 is a circuit schematic of an example tunable capacitor arrangement that may be included in a package substrate, in accordance with various embodiments.

FIGS. 3A-3G are various views of an implementation of the tunable capacitor arrangement of FIG. 2, before tuning operations, in a package substrate, in accordance with various embodiments.

FIGS. 4A-4D are various views of the tunable capacitor arrangement of FIG. 3 after a tuning operation, in accordance with various embodiments.

FIG. 5 is a detailed view of an example filament that may be included in the tunable capacitor arrangement of FIGS. 3 and 4, in accordance with various embodiments.

FIG. 6 is a circuit schematic of another example tunable capacitor arrangement that may be included in a package substrate, in accordance with various embodiments.

FIGS. 7A and 7B are side, cross-sectional views of an implementation of the tunable capacitor arrangement of FIG. 6 before and after a tuning operation, respectively, in accordance with various embodiments.

FIGS. 8A and 8B are side, cross-sectional views of an implementation of the tunable capacitor arrangement of FIG. 6 before and after a tuning operation, respectively, in accordance with various embodiments.

FIGS. 9A and 9B are side, cross-sectional views of an implementation of the tunable capacitor arrangement of FIG. 6 before and after a tuning operation, respectively, in accordance with various embodiments.

FIGS. 10A and 10B are side, cross-sectional views of an implementation of the tunable capacitor arrangement of FIG. 6 before and after a tuning operation, respectively, in accordance with various embodiments.

FIGS. 11A and 11B are side, cross-sectional views of an implementation of the tunable capacitor arrangement of FIG. 6 before and after a tuning operation, respectively, in accordance with various embodiments.

FIGS. 12A and 12B are side, cross-sectional views of an implementation of the tunable capacitor arrangement of FIG. 6 before and after a tuning operation, respectively, in accordance with various embodiments.

FIGS. 13A and 13B are side, cross-sectional views of an implementation of the tunable capacitor arrangement of FIG. 6 before and after a tuning operation, respectively, in accordance with various embodiments.

FIGS. 14A and 14B are side, cross-sectional views of an implementation of the tunable capacitor arrangement of FIG. 6 before and after a tuning operation, respectively, in accordance with various embodiments.

FIGS. 15A and 15B are side, cross-sectional views of an implementation of the tunable capacitor arrangement of FIG. 6 before and after a tuning operation, respectively, in accordance with various embodiments.

FIGS. 16A and 16B are side, cross-sectional views of an implementation of the tunable capacitor arrangement of FIG. 6 before and after a tuning operation, respectively, in accordance with various embodiments.

FIG. 17 is a side, cross-sectional view of an example portion of a capacitor that may be included in a tunable capacitor arrangement, in accordance with various embodiments.

FIG. 18 is a top view of a wafer and dies that may be part of an IC package including any of the tunable capacitor arrangements disclosed herein.

FIG. 19 is a side, cross-sectional view of an IC device that may be part of an IC package including any of the tunable capacitor arrangements disclosed herein.

FIG. 20 is a side, cross-sectional view of an IC assembly that may include an IC package including any of the tunable capacitor arrangements disclosed herein.

FIG. 21 is a block diagram of an example electrical device that may include an IC package including any of the tunable capacitor arrangements disclosed herein.

FIG. 22 is a block diagram of an example radio frequency (RF) device that may include an IC package including any of the tunable capacitor arrangements disclosed herein.

### DETAILED DESCRIPTION

Disclosed herein are tunable capacitor arrangements in integrated circuit (IC) package substrates, as well as related methods and devices. For example, in some embodiments, an IC package substrate may include a first embedded capacitor, a second embedded capacitor, and a fuse electrically coupled between the first embedded capacitor and the second embedded capacitor such that when the fuse is in a closed state, the first embedded capacitor and the second embedded capacitor are connected in parallel, and when the fuse is in an open state, the first embedded capacitor and the second embedded capacitor are not connected in parallel.

For many electronic technologies, the drive towards smaller devices with greater functionality runs up against limitations in conventional manufacturing technology. For example, next-generation 5G wireless communication devices may require additional hardware to accommodate an increasing number of filters and communication bands. To accommodate this additional hardware without increasing the overall device size, it may be desirable to attempt to integrate previously discrete, surface-mounted components into the package substrate itself. However, conventional manufacturing techniques may not be able to achieve the dimensional accuracy needed for adequate performance of these integrated components. For example, radio frequency (RF) devices conventionally include passive elements (e.g., capacitors and inductors) as part of the filter hardware. In order for the filters to target the intended frequency ranges, the capacitance values of the capacitors must be accurate. Package substrate manufacturing tolerances, however, can lead to significant variation in the capacitance values of substrate-integrated capacitors, and detuned circuits with the wrong capacitance values can lead to transmission into adjacent frequency bands.

The structures and techniques disclosed herein may enable accurate substrate-integrated capacitors. Consequently, the embodiments disclosed herein may enable the manufacture of hardware that is compactly integrated into desirably sized devices, accelerating adoption of next-generation communication technology and facilitating its use in a broader array of devices.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The drawings are not necessarily to scale. Although many of the drawings illustrate rectilinear structures with flat walls and right-angle corners, this is simply for ease of illustration, and actual devices made using these techniques will exhibit rounded corners, surface roughness, and other features.

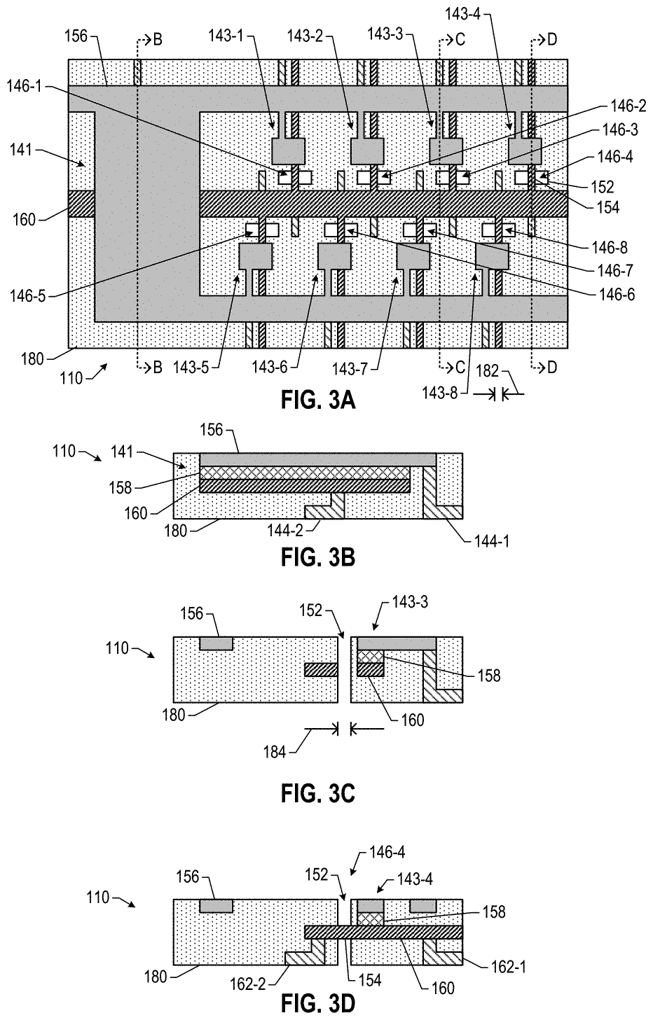

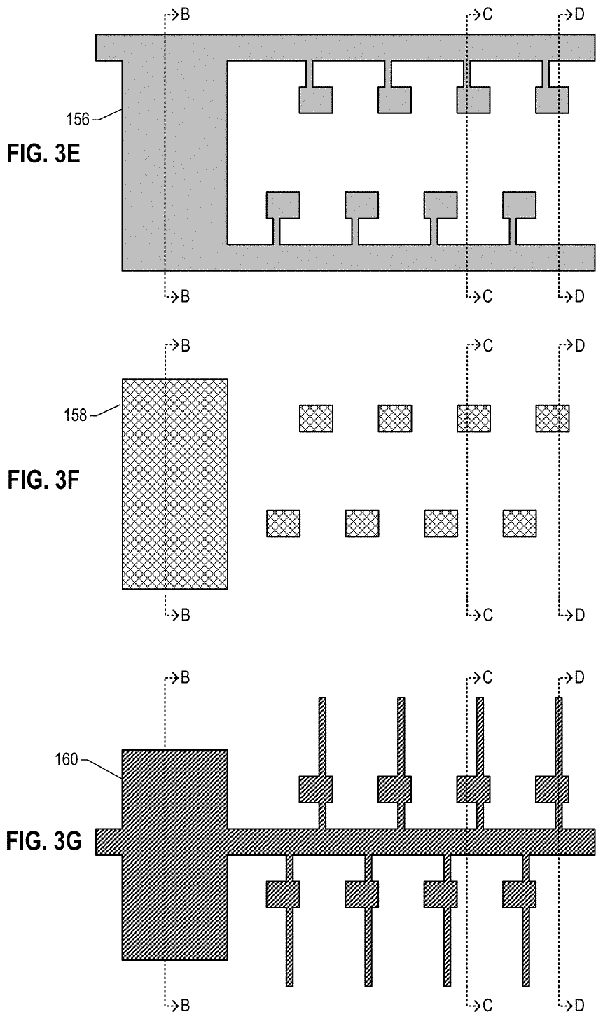

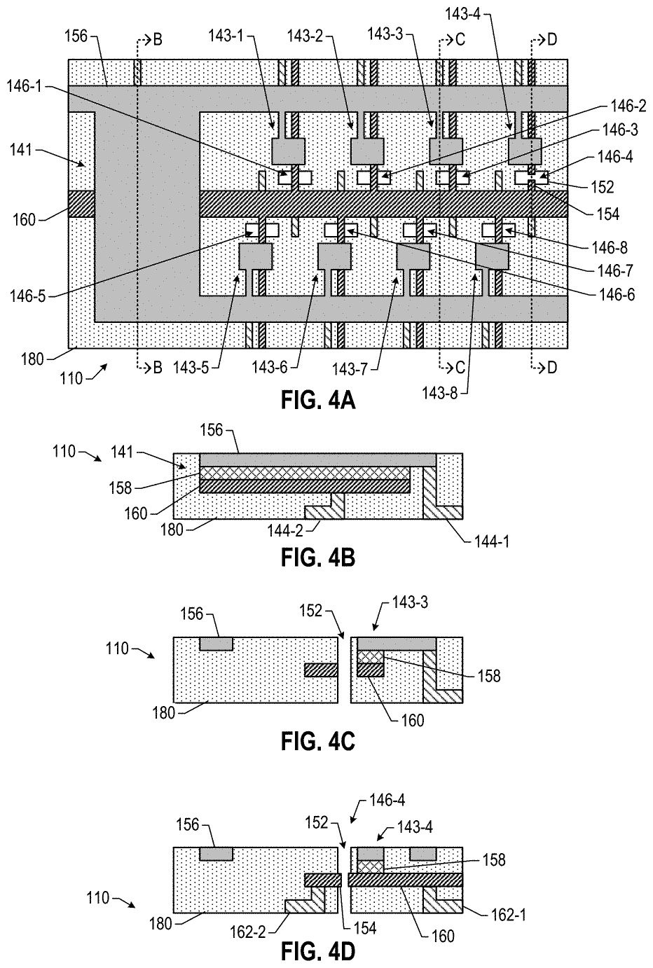

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous. When used to describe a range of dimensions, the phrase “between X and Y” represents a range that includes X and Y. For ease of discussion, the phrase “FIG. 3” may be used to refer to the collection of drawings of FIGS. 3A-3G, the phrase “FIG. 4” may be used to refer to the collection of drawings of FIGS. 4A-4D, etc.

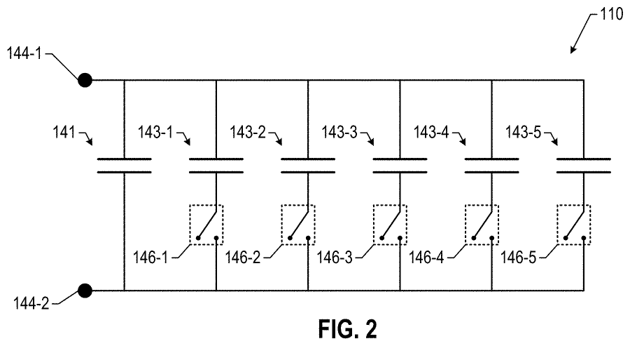

A number of examples of tunable capacitor arrangements 110 in IC packages are disclosed herein. Although these arrangements 110 may be separately discussed for ease of illustration, any suitable ones of these arrangements 110 may be combined in an IC package. For example, any of the arrangements of FIGS. 2-5 may be used in combination with any of the arrangements 110 of FIGS. 6-16, or any of the tunable capacitor arrangements 110 of FIGS. 6-16 may be used in combination with any of the other arrangements 110 of FIGS. 6-16. These particular examples of combinations are simply illustrative, and any suitable combination of any of the embodiments disclosed herein is within the scope of this disclosure.

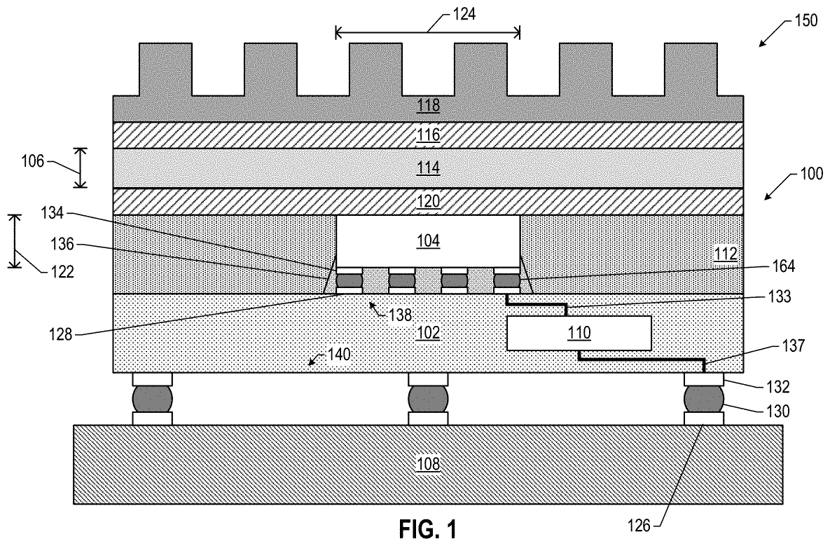

FIG. 1 is a side, cross-sectional view of an IC assembly 150 including an IC package 100 with an example tunable capacitor arrangement 110 in a package substrate 102, in accordance with various embodiments. An IC die 104 is coupled to the package substrate 102; the IC die 104 may be any suitable device, such as a processing die, a memory die, a power amplifier (PA), a switching die, a resonator, etc. Although FIG. 1 depicts only a single IC die 104, this is simply for ease of illustration, and any of the IC packages 100 or IC assemblies 150 disclosed herein may include any desired number of additional components (or fewer components, as appropriate). For example, any of the IC packages 100 disclosed herein may include passive components (e.g., resistors, inductors, capacitors, or combinations thereof) disposed at either face of the package substrate 102 or in any other suitable location. In another example, any of the IC packages 100 disclosed herein may include active components (e.g., transistors) disposed at either face of the package substrate 102, embedded in the package substrate 102, or in any other suitable location.

The package substrate 102 may include a face 140 and an opposing face 138, and the IC die 104 may be coupled to the face 138. The package substrate 102 may include a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the top and bottom surfaces, or between different locations on the top surface, and/or between different locations on the bottom surface. These conductive pathways may take the form of any of the interconnect structures 1628 discussed below with reference to FIG. 19 (e.g., including lines and vias). FIG. 1 illustrates conductive contacts 128 at the face 138 of the package substrate 102 electrically coupled to conductive contacts 134 of the IC die 104 by solder bumps 164, but any suitable interconnects (e.g., first-level interconnects, posts, wirebonds, etc.) may be used to couple the IC die 104 to the package substrate 102 in any of the embodiments disclosed herein. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket). An underfill material 136 may be disposed around the solder bumps 164 coupling the IC die 104 to the package substrate 102. An underfill material may provide mechanical support to these interconnects, helping mitigate the risk of cracking or delamination due to differential thermal expansion between the package substrate 102 and the IC die 104.

As illustrated in FIG. 1, and others of the accompanying drawings, conductive contacts 132 may be disposed at the face 140 of the package substrate 102, and solder balls 130 may be disposed thereon. Conductive pathways (not shown) in the package substrate 102 may electrically couple the conductive contacts 128 to the conductive contacts 132, and/or some of the conductive contacts 128 to others of the conductive contacts 128. These conductive pathways may also conductively couple a tunable capacitor arrangement 110 in the package substrate to any of the conductive contacts; in particular, one or more conductive pathways 133 may conductively couple the tunable capacitor arrangement 110 to the conductive contacts 128, and/or one or more conductive pathways 137 may conductively couple the tunable capacitor arrangement 110 to the conductive contacts 132. In the IC assembly 150 of FIG. 1, the IC package 100 is illustrated as coupled to a circuit board 108 (e.g., a motherboard); in particular, the conductive contacts 132 may be electrically coupled to conductive contacts 126 of the circuit board 108 by the solder balls 130 (e.g., for a ball grid array (BGA) package), but any suitable interconnects may be used (e.g., pins in a pin grid array (PGA) package or lands in a land grid array (LGA) package). In other IC assemblies, an IC package 100 (e.g., in accordance with any of the embodiments disclosed herein) may be coupled to another IC package, a package interposer, or any other suitable support that may take the place of the circuit board 108. In some such embodiments, the package substrate 102 may itself act as an interposer in an IC package or assembly having another package substrate. Further, although the IC package 100 of FIG. 1 (and others of the accompanying drawings) includes IC die 104 coupled directly to the package substrate 102, in any of the embodiments disclosed herein, an intermediate component may be disposed between the IC die 104 and the package substrate 102 (e.g., an interposer, a silicon bridge, an organic bridge, etc.).

The IC package 100 may further include a mold compound 112 disposed around the IC die 104, a heat spreader 114 above the IC die 104, and a thermal interface material (TIM) 120 between the IC die 104 and the heat spreader 114. The mold compound 112 may have a lower thermal conductivity than the heat spreader 114, and a lower thermal conductivity than the TIM 120. In some embodiments, the mold compound 112 may include an epoxy matrix with one or more filler materials (e.g., silica). The TIM 120 and the heat spreader 114 may have high thermal conductivity, and may facilitate the spreading and removal of heat away from the IC die 104 (and toward the heat sink 118, as discussed below). The heat spreader 114 may also be referred to as a “lid.” In some embodiments, the heat spreader 114 may include copper, aluminum, or nickel. In some embodiments, the heat spreader 114 may include copper plated with nickel (e.g., a layer of nickel having a thickness between 5 microns and 10 microns). In some embodiments, the heat spreader 114 may include nickel-plated aluminum. In some embodiments, the heat spreader 114 may include ceramics with good thermal conductivity (e.g., ceramics including diamond or aluminum nitride), or any combination of the materials discussed herein. The TIM 120 may include a polymer TIM, a solder TIM, or a combination thereof. A solder TIM 120 may include an indium-based solder, such as a pure indium solder or an indium alloy solder (e.g., an indium-tin solder, an indium-silver solder, an indium-gold solder, an indium-nickel solder, or an indium-aluminum solder). In embodiments in which the TIM 120 includes a solder TIM, the IC die 104 may have an adhesion material region (not shown) facing the TIM 120. The adhesion material region may serve to wet the TIM 120, and may include gold, silver, or indium.

The heat spreader 114 illustrated in FIG. 1 (and others of the accompanying figures) is shown as substantially planar above the rest of the IC package 100, but in any of the embodiments disclosed herein, the heat spreader 114 may include leg portions that extend toward the package substrate 102 and are secured to the package substrate 102 and/or pedestals, ribs, or other three-dimensional features. In some embodiments, the heat spreader 114 may be formed in situ above the rest of the IC package 100 by plating, additive manufacturing, or another technique, while in other embodiments, the heat spreader 114 may be manufactured separately from the rest of the IC package 100 (e.g., by stamping) and then brought into thermal contact with the rest of the IC package 100.

The dimensions of the elements of the IC package 100 of FIG. 1 (and others of the accompanying figures) may take any suitable values. For example, in some embodiments, a height 122 of the IC die 104 may be between 100 microns and 800 microns. In some embodiments, a width 124 of the IC die 104 may be between 0.5 millimeters and 10 millimeters (e.g., between 1 millimeter and 5 millimeters). In some embodiments, a thickness 106 of a heat spreader 114 may be between 250 microns and 5 millimeters (e.g., between 250 microns and 2 millimeters when the heat spreader 114 is plated or otherwise formed in situ, or between 0.5 millimeters and 5 millimeters when the heat spreader 114 is manufactured separately).

The IC assembly 150 of FIG. 1 also includes a heat sink 118 and a TIM 116 between the heat sink 118 and the IC package 100. The TIM 116 may aid in the transfer of heat from the IC package 100 (e.g., from the heat spreader 114) to the heat sink 118, and the heat sink 118 may be designed to readily dissipate heat into the surrounding environment, as known in the art (e.g., using fins, as shown). In some embodiments, the TIM 116 may be a polymer TIM. Any of the IC packages 100 disclosed herein may be part of an IC assembly 150 including a heat sink 118 and a TIM 116.

One or more tunable capacitor arrangements 110 may be included in the package substrate 102. As used herein, a “tunable capacitor arrangement” may refer to an arrangement of multiple capacitors whose electrical interconnections may be adjusted after manufacture of the package substrate 102 in order to achieve a desired total capacitance. Electrical interconnections among the capacitors in a tunable capacitor arrangement 110 may be adjusted by supplying electrical signals at select points on a surface of the package substrate 102 (e.g., to cause a fuse to open or to cause an open circuit to close, as discussed below with reference to FIGS. 2-5) or by adding or subtracting material at a surface of the package substrate 102 (e.g., as discussed below with reference to FIGS. 6-15). For example, a tunable capacitor arrangement 110 may include a main capacitor and one or more tuning capacitors; electrical interconnections among the main and tuning capacitors may be adjusted so that one or more of the tuning capacitors are connected in parallel with the main capacitor. As known in the art, and as discussed further below, the total capacitance of multiple capacitors arranged in parallel is the sum of the individual capacitances. Consequently, increasing the number of tuning capacitors in parallel with the main capacitor may increase the total capacitance of the tunable capacitor arrangement, and decreasing the number of tuning capacitors in parallel with the main capacitor may decrease the total capacitance. Particular examples of tunable capacitor arrangements 110 are discussed in detail below with reference to FIGS. 2-15.

Although FIG. 1 illustrates the tunable capacitor arrangement 110 as embedded in the package substrate 102 and spaced apart from the faces 138 and 140, in other embodiments, the tunable capacitor arrangement 110 may be disposed at the face 138 or at the face 140. Further, although FIG. 1 illustrates a single tunable capacitor arrangement 110 in the package substrate 102, a package substrate 102 may include one or more tunable capacitor arrangements 110, as desired.

FIG. 2 is a circuit schematic of an example tunable capacitor arrangement 110 that may be included in a package substrate 102, in accordance with various embodiments. As illustrated in FIG. 2, a tunable capacitor arrangement 110 may include a main capacitor 141 coupled between a terminal 144-1 and a terminal 144-2, and a plurality of tuning capacitors 143 coupled to the terminal 144-1 and selectively coupled to the terminal 144-2 via associated controllable connections 146. When a controllable connection 146 associated with a particular tuning capacitor 143 is closed, the tuning capacitor 143 is connected in parallel with the main capacitor 141 (and thus contributes to the total capacitance between the terminals 144); when the controllable connection 146 associated with a particular tuning capacitor 143 is open, the tuning capacitor 143 is not connected in parallel with the main capacitor 141 (and does not contribute to the total capacitance between the terminals 144). The particular number of tuning capacitors 143 depicted in FIG. 2 (and others of the accompanying figures) is simply illustrative, and any desired number of tuning capacitors 143 may be included in a tunable capacitor arrangement 110 (e.g., ten or more).

In some embodiments, a controllable connection 146 may be initially open, and in response to some intervention, may become closed. In some such embodiments, the state of the controllable connection 146 may be reversible in that, in response to another intervention, the closed controllable connection 146 may become open again. For example, the controllable connection 146 may include a reversible switch (e.g., a microelectromechanical systems (MEMS) switch or breaker). In other embodiments, the state of the controllable connection 146 may not be reversible in that, once the controllable connection 146 is closed, it remains closed. For example, the controllable connection 146 may include a MEMS switch or beam that becomes plastically (irreversibly) deformed upon switching from the open to the closed position.

In some embodiments, a controllable connection 146 may be initially closed, and in response to some intervention, may become open. In some such embodiments, the state of the controllable connection 146 may be reversible in that, in response to another intervention, the open controllable connection 146 may become closed again. For example, the controllable connection 146 may include a reversible switch (e.g., a MEMS switch or breaker). In other embodiments, the state of the controllable connection 146 may not be reversible in that, once the controllable connection 146 is open, it remains open. For example, the controllable connection 146 may include a fuse that is nominally closed until a mechanical break causes the fuse to enter an open state.

The controllable connections 146 may be selectively set in their open or closed state to achieve a desired arrangement among the capacitors 141/143 and thus a desired capacitance between the terminals 144. As noted above, this may allow manufacturers to compensate for deviations in nominal capacitance that arise from nonzero manufacturing tolerances. For example, assume that a total capacitance of 10 picofarads (pF)+/−0.01 pF is desired. If the package substrate 102 were fabricated with a single capacitor having a nominal capacitance of 10 pF, manufacturing tolerances in the manufacture of the package substrate 102 may mean that the actual capacitance of the single capacitor is significantly greater or less than 10 pF (e.g., when the manufacturing tolerance is +/−10%, the actual capacitance of the single capacitor may be as low as 9 pF and as high as 11 pF). In an RF setting, the deviation of the actual capacitance of this single capacitor from its nominal value may, for example, cause the filter circuit of which the capacitor is a part to fail to operate in the desired frequency band.

Continuing this example, assume instead that the tunable capacitor arrangement 110 of FIG. 2 is used, the main capacitor 141 is fabricated with a nominal capacitance of 9 pF, that 21 tuning capacitors 143 are fabricated with nominal capacitances of 0.1 pF, and that the controllable connections 146 are fuses that can be blown on demand (e.g., as discussed below with reference to FIGS. 3-5) to disconnect the associated tuning capacitors 143 from the circuit. Assuming the same+/−10% manufacturing tolerance, if the variation from nominal capacitances is −10%, all of the controllable connections 146 may be closed (e.g., none of the fuses are blown) and the total capacitance between the terminals 144 may be approximately 0.9*(9+21*0.1)=9.99 pF. If the variation from nominal capacitances is +10%, only one of the controllable connections 146 may be closed (e.g., all but one of the fuses may be blown), and the total capacitance between the terminals 144 may be approximately 1.1*(9+1*0.1)=10.01 pF. Thus, selective setting of the controllable connections 146 may allow the total capacitance between the terminals 144 to be maintained in the desired 10 pF+/−0.01 pF range. As noted above, the tunable capacitor arrangement 110 of FIG. 2 may enable a desired resolution in capacitance to be achieved even in the face of large manufacturing variations.

The tunable capacitor arrangement 110 of FIG. 2 may be implemented in any of a number of ways. For example, FIGS. 3A-3G are various views of an implementation of the tunable capacitor arrangement 110 of FIG. 2, before tuning operations, that may be implemented in a package substrate 102, in accordance with various embodiments. In particular, FIG. 3A is a top view, FIG. 3B is a cross-sectional view through the section B-B of FIG. 3A, FIG. 3C is a cross-sectional view through the section C-C of FIG. 3A, FIG. 3D is a cross-sectional view through the section D-D of FIG. 3A, FIG. 3E is a top view of the first plate structure 156, FIG. 3F is a top view of the capacitor dielectric structure 158, and FIG. 3G is a top view of the second plate structure 160. Note that, in FIG. 3A, not all of the dielectric material 180 is depicted so that features that are otherwise under portions of the dielectric material 180 may be viewed (e.g., various ones of the terminals 144 and 162). As discussed further below, the tunable capacitor arrangement 110 of FIG. 3 may be tuned by the selective application of electrical signals, and thus may be spaced apart from the faces 138 and 140 of the package substrate 102, if desired.

In the tunable capacitor arrangement 110 of FIG. 3, a first plate structure 156 provides the “top” capacitor plates of the main capacitor 141 and the tuning capacitors 143. The second plate structure 160 provides the “bottom” capacitor plates of the main capacitor 141 and the tuning capacitors 143, and includes filaments 154 that span air gaps 152 in the surrounding dielectric material 180 (e.g., an organic dielectric, such as an organic buildup film); these filaments 154 in the corresponding air gaps 152 provide the controllable connections 146, as discussed further below. The capacitor dielectric structure 158 provides the capacitor dielectric between the plates of the main capacitor 141 and the tuning capacitors 143; in some embodiments, the material composition of the capacitor dielectric structure 158 may be different than the material composition of the dielectric material 180.

As initially fabricated, all of the filaments 154 may be in place and continuous, and thus all of the controllable connections 146 may be closed and all of the tuning capacitors 143 may be in parallel with the main capacitor 141. To open one of the controllable connections 146, a voltage of sufficient magnitude may be applied across the terminals 162-1 and 162-2 (which may extend to, and be exposed at, the face 138 and/or the face 140 of the package substrate 102 for ready electrical access) to cause the associated filament 154 in an air gap 152 to heat up, melt, and eventually break, opening the circuit between the terminals 162-1 and 162-2 and disconnecting the associated tuning capacitor 143 from the circuit. Utilizing an air gap 152 around the filament 154 may provide greater thermal insulation than having the filament 154 surrounded by (and in contact with) the dielectric material 180, allowing the heating to be more localized in the filament 154 (instead of being conducted to nearby regions in the package substrate 102) and thus allowing the “fuse” to break at lower voltages, if desired. FIG. 4 illustrates a tunable capacitor arrangement 110 subsequent to applying ample voltage across the terminals 162 to cause the filament 154 of the controllable connection 146-4 to break (and thereby “open”).

The elements of the tunable capacitor arrangement 110 of FIG. 3 may have any suitable dimensions. For example, in some embodiments, the width 182 of the filaments 154 may be between 2 microns and 10 microns. In some embodiments, the width 184 of the air gaps 152 may be between 50 microns and 250 microns. The area of the capacitor plates included in the first plate structure 156 and the second plate structure 160 may be selected to achieve a desired capacitance for the main capacitor 141 and the tuning capacitors 143 (since capacitance scales with area, as known in the art). The particular shapes of the first plate structure 156, second plate structure 160, capacitor dielectric structure 158, air gaps 152, terminals 144, and terminals 162 are simply illustrative, and any suitable shapes and arrangement may be used. Further, any desired combination of the controllable connections 146 of the tunable capacitor arrangement 110 of FIGS. 3-4 may be caused to “open” to achieve a desired capacitance across the terminals 144, as discussed above.

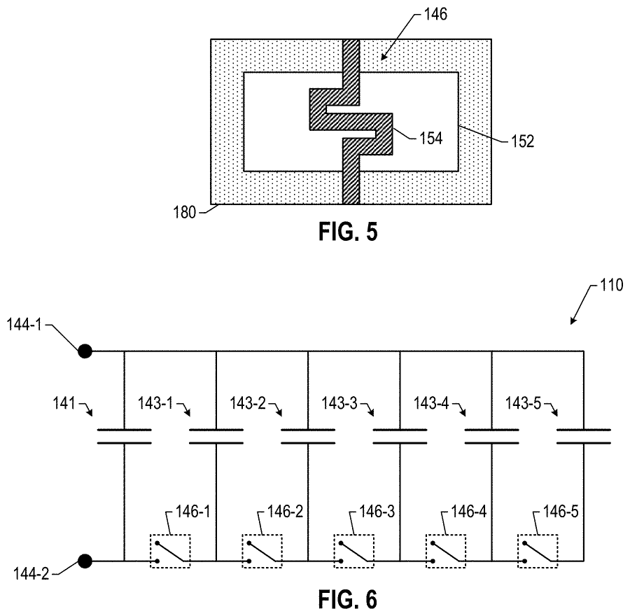

FIGS. 3-4 illustrate the filaments 154 as being substantially linear in shape as they span the associated air gaps 152. This need not be the case, and the shape of the filaments 154 may take any suitable form. For example, FIG. 5 is a detailed top view of a filament 154 that has a serpentine shape across an air gap 152; such serpentine filaments 154 may be longer than their linear counterparts and thus may require a smaller voltage to break. Serpentine filaments 154, or filaments 154 having any other desired shape, may be used instead of, or in addition to, linear filaments 154 in the tunable capacitor arrangements 110 discussed above with reference to FIGS. 3-4.

FIG. 6 is a circuit schematic of another example tunable capacitor arrangement 110 that may be included in a package substrate 102, in accordance with various embodiments. The circuit of FIG. 6 is similar to the circuit of FIG. 2, with a main capacitor 141 coupled between a terminal 144-1 and a terminal 144-2, and a plurality of tuning capacitors 143 coupled to the terminal 144-1 and selectively coupled to the terminal 144-2 via associated controllable connections 146, but the controllable connections 146 are arranged in series; in order for a particular tuning capacitor 143-x to be connected in parallel with the main capacitor 141 (and thus to contribute to the total capacitance between the terminals 144), the controllable connection 146-x associated with the tuning capacitor 143-x, and all of the controllable connections 146 between the controllable connection 146-x and the terminal 144-2 (if any) must also be closed. If these conditions are not satisfied, the tuning capacitor 143-x is not connected in parallel with the main capacitor 141 (and does not contribute to the total capacitance between the terminals 144). The controllable connections 146 of the tunable capacitor arrangement 110 of FIG. 6 may take any of the forms disclosed herein.

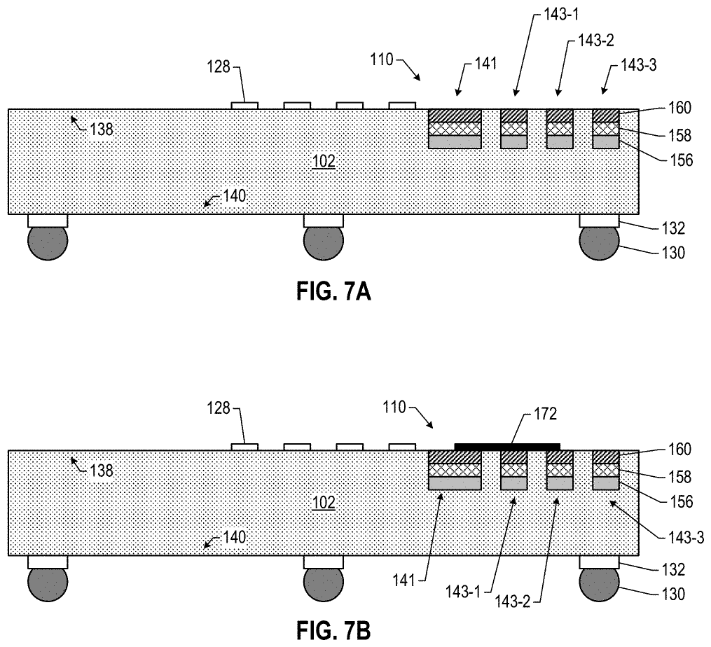

The tunable capacitor arrangement 110 of FIG. 6 may be implemented in any of a number of ways. For example, the tunable capacitor arrangements 110 discussed above with reference to FIGS. 3-5 may be modified so that the controllable connections 146 (provided by the filaments 154/air gaps 152, as discussed) are arranged in the manner of FIG. 6 instead of in the manner of FIG. 2. Further, FIGS. 7-16 provide side, cross-sectional views of example implementations of the tunable capacitor arrangement 110 of FIG. 6. In particular, the “A” subfigures illustrate the tunable capacitor arrangements 110 before tuning operations, and the “B” subfigures illustrate the tunable capacitor arrangements 110 after tuning operations. As discussed further below, the tunable capacitor arrangements 110 of FIGS. 7-16 may be tuned by the addition, removal, or reconfiguration of conductive material or elements at a face 138 or 140 of the package substrate 102. In some embodiments, the structures of the “A” subfigures may be fabricated as part of the manufacture of the package substrate 102, and the structures of the “B” subfigures may represent tuning operations performed by another entity (e.g., the integrator also responsible for attaching the IC die 104, etc.)

FIGS. 7A and 7B are side, cross-sectional views of an implementation of the tunable capacitor arrangement 110 of FIG. 6 in a package substrate 102 before and after a tuning operation, respectively, in accordance with various embodiments. In particular, FIG. 7A illustrates a main capacitor 141 and multiple tuning capacitors 143 implemented by a first plate structure 156, a capacitor dielectric structure 158, and a second plate structure 160. The first plate structure 156 may be in one metal layer of the package substrate 102, and the second plate structure 160 may be in another layer of the package substrate 102 (e.g., in the top metal layer, closes to the “die-side” face 138). The second plate structure 160 may be electrically exposed at the face 138 of the package substrate 102. The first plate structure 156 may electrically connect all of the capacitors 141/143 (out of the plane of the drawing), while the second plate structure 160 may have the capacitors 141/143 electrically isolated from each other (equivalent to having all of the controllable connections 146 in the tunable capacitor arrangement 110 of FIG. 6 in the “open” state). To tune the tunable capacitor arrangement 110 of FIG. 7A, a conductive material 172 may be deposited on the face 138 of the package substrate 102 (e.g., in an opening of a solder mask, not shown) to electrically connect desired ones of the tuning capacitors 143 with the main capacitor 141. In particular, FIG. 7B illustrates a conductive material 172 deposited on the face 138 so that the tuning capacitors 143-1 and 143-2 are connected in parallel with the main capacitor 141 (i.e., the controllable connections 146-1 and 146-2 are “closed” by the presence of the conductive material 172), while the tuning capacitor 143-3 is disconnected (i.e., the controllable connection 146-3 remains “open”). The conductive material 172 may be deposited on the face 138 in any desired manner to achieve a desired connectivity between the main capacitor 141 and the tuning capacitors 143, and thereby a desired capacitance. In some embodiments, the conductive material 172 may be a metal (e.g., copper), a solder material (e.g., a printed solder paste), a conductive ink, a conductive adhesive, or another conductive material. In some embodiments, the thickness of the conductive material 172 may be between 10 microns and 100 microns.

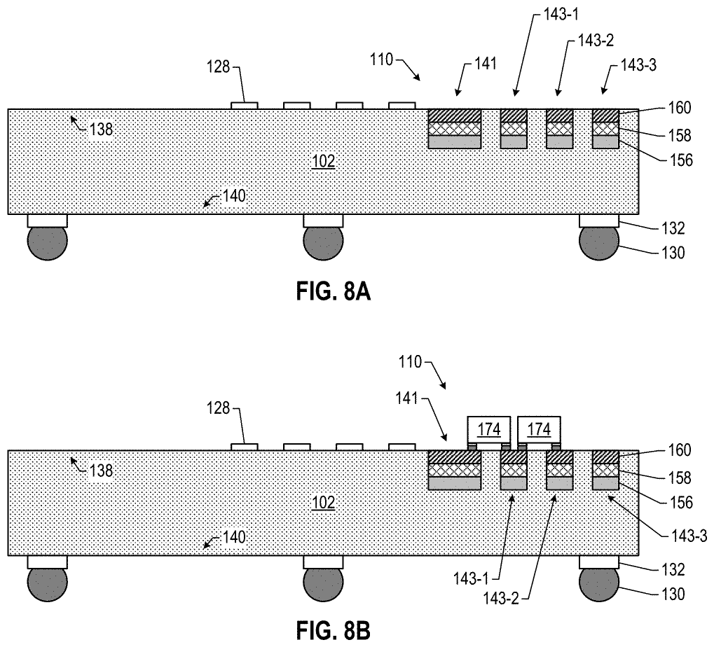

FIGS. 8A and 8B are side, cross-sectional views of another implementation of the tunable capacitor arrangement 110 of FIG. 6 in a package substrate 102 before and after a tuning operation, respectively, in accordance with various embodiments. The structure of FIG. 8A is the same as the structure of FIG. 7A, but the method of tuning the tunable capacitor arrangement 110 may be different, as illustrated in FIG. 8B. To tune the tunable capacitor arrangement 110 of FIG. 8A, zero-ohm resistors 174 may be coupled to the face 138 of the package substrate 102 to electrically connect desired ones of the tuning capacitors 143 with the main capacitor 141. In particular, FIG. 8B illustrates one zero-ohm resistor 174 coupled to the face 138 to electrically connect (i.e., bridge the gap) between the portion of the second plate structure 160 corresponding to the main capacitor 141 with the portion of the second plate structure 160 corresponding to the tuning capacitor 143-1, and another zero-ohm resistor 174 coupled to the face 138 to electrically connect the portion of the second plate structure 160 corresponding to the tuning capacitor 143-1 with the portion of the second plate structure 160 corresponding to the tuning capacitor 143-2. In FIG. 8B, the tuning capacitors 143-1 and 143-2 are connected in parallel with the main capacitor 141 (i.e., the controllable connections 146-1 and 146-2 are “closed” by the presence of the zero-ohm resistors 174), while the tuning capacitor 143-3 is disconnected (i.e., the controllable connection 146-3 remains “open”). In some embodiments, the zero-ohm resistors 174 may be surface-mounted discrete components, wirebonds, or any other suitable element. Zero-ohm resistors 174 may be used to bridge portions of the tunable capacitor array 110 in any desired manner to achieve a desired connectivity between the main capacitor 141 and the tuning capacitors 143, and thereby a desired capacitance.

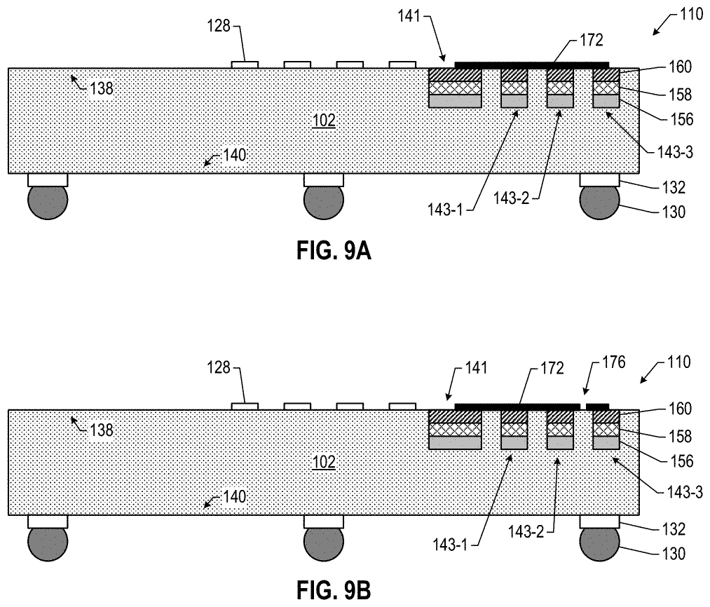

FIGS. 9A and 9B are side, cross-sectional views of another implementation of the tunable capacitor arrangement 110 of FIG. 6 in a package substrate 102 before and after a tuning operation, respectively, in accordance with various embodiments. In particular, FIG. 9A has a structure similar to that of FIG. 7A, but in which a conductive material 172 on the face 138 provides electrical connections between the portions of the second plate structure 160 corresponding to the main capacitor 141 and the tuning capacitors 143 (equivalent to having all of the controllable connections 146 in the tunable capacitor arrangement 110 of FIG. 6 in the “closed” state). The conductive material 172 may take any of the forms discussed above. To tune the tunable capacitor arrangement 110 of FIG. 9A, the conductive material 172 may be selectively removed to “disconnect” one or more of the tuning capacitors 143 from the remainder of the capacitors 141/143. For example, FIG. 9B illustrates a cut 176 in the conductive material 172 so that the tuning capacitors 143-1 and 143-2 remain connected in parallel with the main capacitor 141 (i.e., the controllable connections 146-1 and 146-2 are “closed” by the presence of the conductive material 172), while the tuning capacitor 143-3 is disconnected (i.e., the controllable connection 146-3 is made “open”). Portions of the conductive material 172 may be selectively removed using any suitable technique, such as laser cutting or mechanical cutting (e.g., sawing or drilling). Although FIG. 9B illustrates the cut 176 as only cutting the conductive material 172, in some embodiments, the cut 176 may extend further into the package substrate 102 (e.g., into an organic dielectric material of the package substrate 102) and may leave a recess in the package substrate 102 (not shown). Portions of the conductive material 172 may be selectively removed in any desired manner to achieve a desired connectivity between the main capacitor 141 and the tuning capacitors 143, and thereby a desired capacitance.

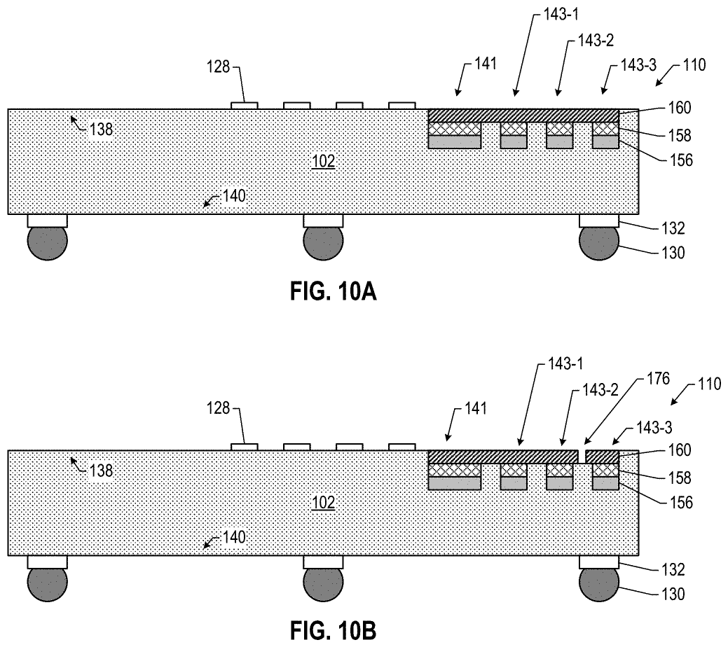

FIGS. 10A and 10B are side, cross-sectional views of another implementation of the tunable capacitor arrangement 110 of FIG. 6 in a package substrate 102 before and after a tuning operation, respectively, in accordance with various embodiments. In particular, FIG. 10A has a structure similar to that of FIG. 9A, but in which the second plate structure 160 (exposed at the face 138) includes electrical connections between the portions of the second plate structure 160 corresponding to the main capacitor 141 and the tuning capacitors 143 (equivalent to having all of the controllable connections 146 in the tunable capacitor arrangement 110 of FIG. 6 in the “closed” state). To tune the tunable capacitor arrangement 110 of FIG. 10A, portions of the second plate structure 160 may be selectively removed to “disconnect” one or more of the tuning capacitors 143 from the remainder of the capacitors 141/143. For example, FIG. 10B illustrates a cut 176 in the second plate structure 160 so that the tuning capacitors 143-1 and 143-2 remain connected in parallel with the main capacitor 141 (i.e., the controllable connections 146-1 and 146-2 are “closed”), while the tuning capacitor 143-3 is disconnected (i.e., the controllable connection 146-3 is made “open”). Portions of the second plate structure 160 may be selectively removed using any suitable technique, such as laser cutting or mechanical cutting (e.g., sawing or drilling). Although FIG. 10B illustrates the cut 176 as only cutting the second plate structure 160, in some embodiments, the cut 176 may extend further into the package substrate 102 (e.g., into an organic dielectric material of the package substrate 102) and may leave a deeper recess in the package substrate 102 (not shown). Portions of the second plate structure 160 may be selectively removed in any desired manner to achieve a desired connectivity between the main capacitor 141 and the tuning capacitors 143, and thereby a desired capacitance.

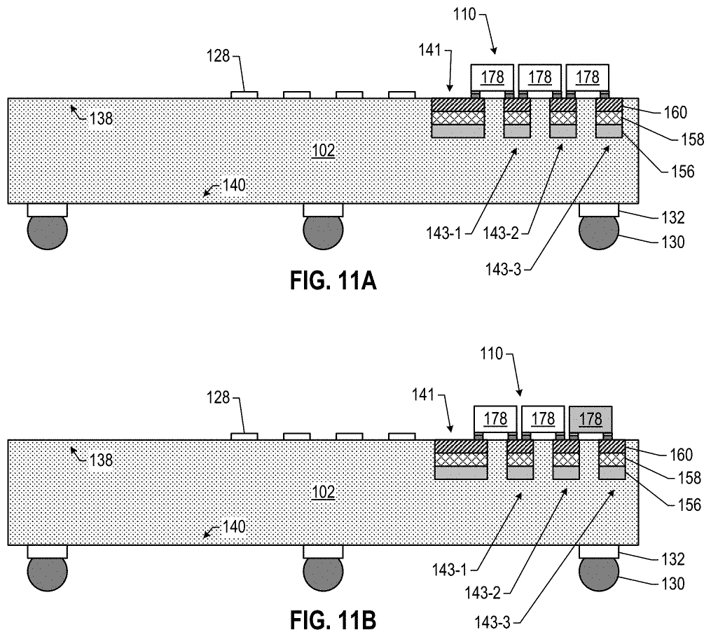

FIGS. 11A and 11B are side, cross-sectional views of another implementation of the tunable capacitor arrangement 110 of FIG. 6 in a package substrate 102 before and after a tuning operation, respectively, in accordance with various embodiments. In particular, FIG. 11A has a structure similar to that of FIG. 7A, but in which fuses 178 coupled to the face 138 provide electrical connections between the portions of the second plate structure 160 corresponding to the main capacitor 141 and the tuning capacitors 143 (equivalent to having all of the controllable connections 146 in the tunable capacitor arrangement 110 of FIG. 6 in the “closed” state). To tune the tunable capacitor arrangement 110 of FIG. 11A, the fuses 178 may be selectively “blown” to “disconnect” one or more of the tuning capacitors 143 from the remainder of the capacitors 141/143. For example, FIG. 11B illustrates a greyed-out blown fuse 178 between the tuning capacitor 143-2 and the tuning capacitor 143-3 so that the tuning capacitors 143-1 and 143-2 remain connected in parallel with the main capacitor 141 (i.e., the controllable connections 146-1 and 146-2 are “closed” by the intact fuses 178), while the tuning capacitor 143-3 is disconnected by the blown fuse 178 (i.e., the controllable connection 146-3 is made “open”). Fuses 178 may be selectively blown by applying an adequate voltage and/or current across the fuses 178 (e.g., by test probes or other appropriate equipment). In some embodiments, the fuses 178 may be discrete, surface-mount components, while in other embodiments, the fuses 178 may be wirebonds, solder bridges, or other materials that may be selectively broken (e.g., by the application of adequate voltage/current, as discussed above with reference to the filaments 154). The fuses 178 may be selectively blown in any desired manner to achieve a desired connectivity between the main capacitor 141 and the tuning capacitors 143, and thereby a desired capacitance.

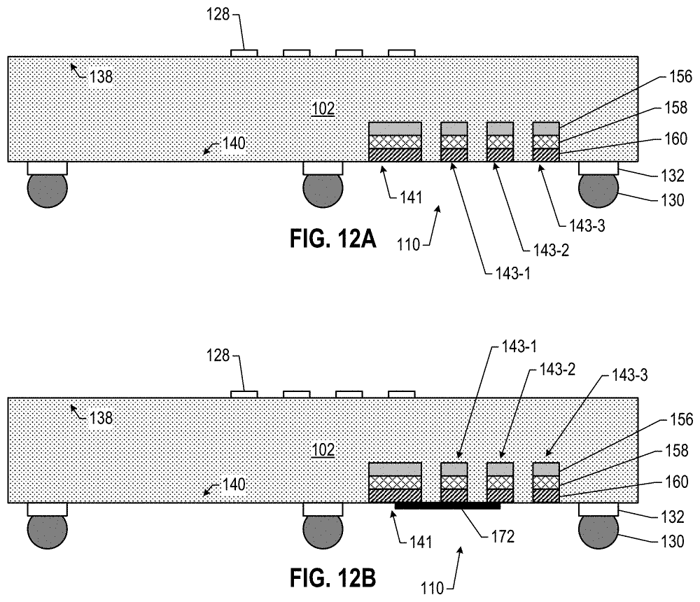

FIGS. 12A and 12B are side, cross-sectional views of an implementation of the tunable capacitor arrangement 110 of FIG. 6 in a package substrate 102 before and after a tuning operation, respectively, in accordance with various embodiments. In particular, FIG. 12A illustrates a main capacitor 141 and multiple tuning capacitors 143 implemented by a first plate structure 156, a capacitor dielectric structure 158, and a second plate structure 160. The first plate structure 156 may be in one metal layer of the package substrate 102, and the second plate structure 160 may be in another layer of the package substrate 102 (e.g., in the bottom metal layer, closes to the “board-side” face 140). The second plate structure 160 may be electrically exposed at the face 140 of the package substrate 102. The first plate structure 156 may electrically connect all of the capacitors 141/143 (out of the plane of the drawing), while the second plate structure 160 may have the capacitors 141/143 electrically isolated from each other (equivalent to having all of the controllable connections 146 in the tunable capacitor arrangement 110 of FIG. 6 in the “open” state). To tune the tunable capacitor arrangement 110 of FIG. 12A, a conductive material 172 may be deposited on the face 140 of the package substrate 102 (e.g., in an opening of a solder mask, not shown) to electrically connect desired ones of the tuning capacitors 143 with the main capacitor 141. In particular, FIG. 12B illustrates a conductive material 172 deposited on the face 140 so that the tuning capacitors 143-1 and 143-2 are connected in parallel with the main capacitor 141 (i.e., the controllable connections 146-1 and 146-2 are “closed” by the presence of the conductive material 172), while the tuning capacitor 143-3 is disconnected (i.e., the controllable connection 146-3 remains “open”). The conductive material 172 may be deposited on the face 140 in any desired manner to achieve a desired connectivity between the main capacitor 141 and the tuning capacitors 143, and thereby a desired capacitance. The conductive material 172 may take any of the forms disclosed herein.

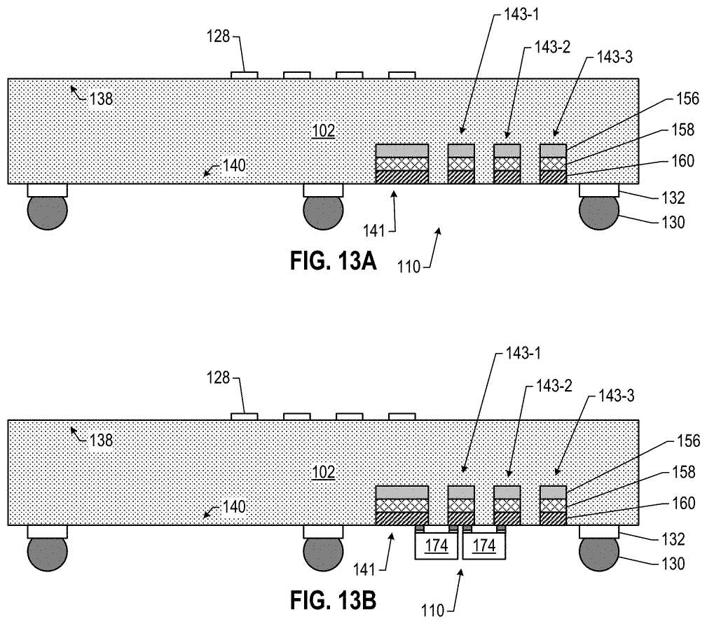

FIGS. 13A and 13B are side, cross-sectional views of another implementation of the tunable capacitor arrangement 110 of FIG. 6 in a package substrate 102 before and after a tuning operation, respectively, in accordance with various embodiments. The structure of FIG. 13A is the same as the structure of FIG. 12A, but the method of tuning the tunable capacitor arrangement 110 may be different, as illustrated in FIG. 13B. To tune the tunable capacitor arrangement 110 of FIG. 13A, zero-ohm resistors 174 may be coupled to the face 140 of the package substrate 102 to electrically connect desired ones of the tuning capacitors 143 with the main capacitor 141. In particular, FIG. 13B illustrates one zero-ohm resistor 174 coupled to the face 140 to electrically connect (i.e., bridge the gap) between the portion of the second plate structure 160 corresponding to the main capacitor 141 with the portion of the second plate structure 160 corresponding to the tuning capacitor 143-1, and another zero-ohm resistor 174 coupled to the face 140 to electrically connect the portion of the second plate structure 160 corresponding to the tuning capacitor 143-1 with the portion of the second plate structure 160 corresponding to the tuning capacitor 143-2. In FIG. 13B, the tuning capacitors 143-1 and 143-2 are connected in parallel with the main capacitor 141 (i.e., the controllable connections 146-1 and 146-2 are “closed” by the presence of the zero-ohm resistors 174), while the tuning capacitor 143-3 is disconnected (i.e., the controllable connection 146-3 remains “open”). The zero-ohm resistors 174 may take any of the forms disclosed herein. As discussed above with reference to FIG. 8, zero-ohm resistors 174 may be used to bridge portions of the tunable capacitor array 110 in any desired manner to achieve a desired connectivity between the main capacitor 141 and the tuning capacitors 143, and thereby a desired capacitance.

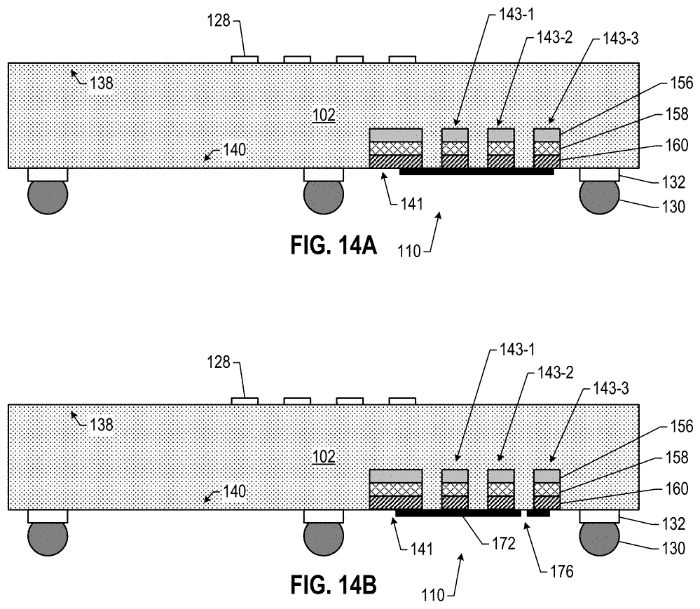

FIGS. 14A and 14B are side, cross-sectional views of another implementation of the tunable capacitor arrangement 110 of FIG. 6 in a package substrate 102 before and after a tuning operation, respectively, in accordance with various embodiments. In particular, FIG. 14A has a structure similar to that of FIG. 12A, but in which a conductive material 172 on the face 140 provides electrical connections between the portions of the second plate structure 160 corresponding to the main capacitor 141 and the tuning capacitors 143 (equivalent to having all of the controllable connections 146 in the tunable capacitor arrangement 110 of FIG. 6 in the “closed” state). The conductive material 172 may take any of the forms discussed herein. To tune the tunable capacitor arrangement 110 of FIG. 14A, the conductive material 172 may be selectively removed to “disconnect” one or more of the tuning capacitors 143 from the remainder of the capacitors 141/143. For example, FIG. 14B illustrates a cut 176 in the conductive material 172 so that the tuning capacitors 143-1 and 143-2 remain connected in parallel with the main capacitor 141 (i.e., the controllable connections 146-1 and 146-2 are “closed” by the presence of the conductive material 172), while the tuning capacitor 143-3 is disconnected (i.e., the controllable connection 146-3 is made “open”). Portions of the conductive material 172 may be selectively removed using any suitable technique, such as laser cutting or mechanical cutting (e.g., sawing or drilling). Although FIG. 14B illustrates the cut 176 as only cutting the conductive material 172, in some embodiments, the cut 176 may extend further into the package substrate 102 (e.g., into an organic dielectric material of the package substrate 102) and may leave a recess in the package substrate 102 (not shown). As discussed above with reference to FIG. 9, portions of the conductive material 172 may be selectively removed in any desired manner to achieve a desired connectivity between the main capacitor 141 and the tuning capacitors 143, and thereby a desired capacitance.

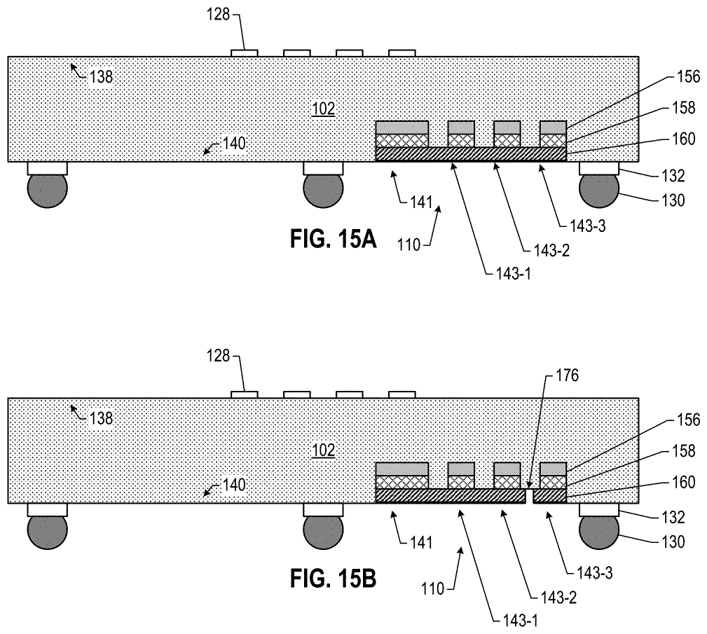

FIGS. 15A and 15B are side, cross-sectional views of another implementation of the tunable capacitor arrangement 110 of FIG. 6 in a package substrate 102 before and after a tuning operation, respectively, in accordance with various embodiments. In particular, FIG. 15A has a structure similar to that of FIG. 14A, but in which the second plate structure 160 (exposed at the face 140) includes electrical connections between the portions of the second plate structure 160 corresponding to the main capacitor 141 and the tuning capacitors 143 (equivalent to having all of the controllable connections 146 in the tunable capacitor arrangement 110 of FIG. 6 in the “closed” state). To tune the tunable capacitor arrangement 110 of FIG. 15A, portions of the second plate structure 160 may be selectively removed to “disconnect” one or more of the tuning capacitors 143 from the remainder of the capacitors 141/143. For example, FIG. 15B illustrates a cut 176 in the second plate structure 160 so that the tuning capacitors 143-1 and 143-2 remain connected in parallel with the main capacitor 141 (i.e., the controllable connections 146-1 and 146-2 are “closed”), while the tuning capacitor 143-3 is disconnected (i.e., the controllable connection 146-3 is made “open”). Portions of the second plate structure 160 may be selectively removed using any suitable technique, such as laser cutting or mechanical cutting (e.g., sawing or drilling). Although FIG. 15B illustrates the cut 176 as only cutting the second plate structure 160, in some embodiments, the cut 176 may extend further into the package substrate 102 (e.g., into an organic dielectric material of the package substrate 102) and may leave a deeper recess in the package substrate 102 (not shown). As discussed above with reference to FIG. 10, portions of the second plate structure 160 may be selectively removed in any desired manner to achieve a desired connectivity between the main capacitor 141 and the tuning capacitors 143, and thereby a desired capacitance.

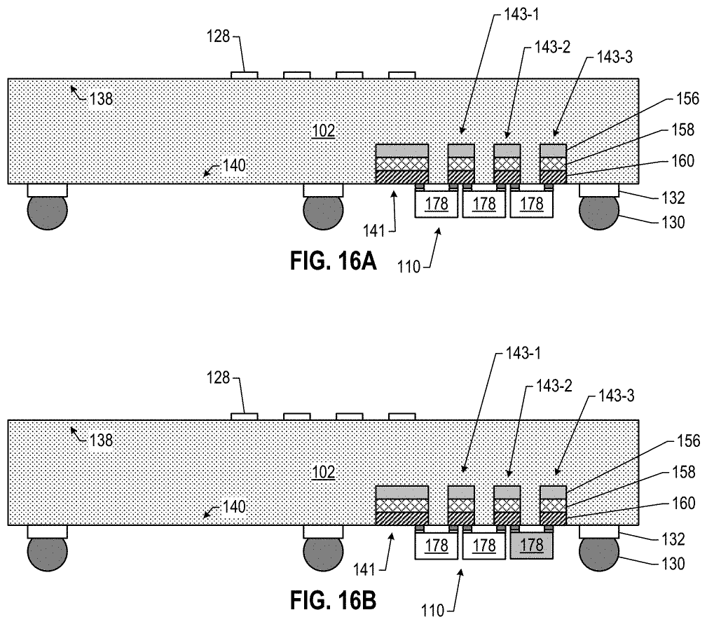

FIGS. 16A and 16B are side, cross-sectional views of another implementation of the tunable capacitor arrangement 110 of FIG. 6 in a package substrate 102 before and after a tuning operation, respectively, in accordance with various embodiments. In particular, FIG. 16A has a structure similar to that of FIG. 12A, but in which fuses 178 coupled to the face 140 provide electrical connections between the portions of the second plate structure 160 corresponding to the main capacitor 141 and the tuning capacitors 143 (equivalent to having all of the controllable connections 146 in the tunable capacitor arrangement 110 of FIG. 6 in the “closed” state). To tune the tunable capacitor arrangement 110 of FIG. 16A, the fuses 178 may be selectively “blown” to “disconnect” one or more of the tuning capacitors 143 from the remainder of the capacitors 141/143. For example, FIG. 16B illustrates a greyed-out blown fuse 178 between the tuning capacitor 143-2 and the tuning capacitor 143-3 so that the tuning capacitors 143-1 and 143-2 remain connected in parallel with the main capacitor 141 (i.e., the controllable connections 146-1 and 146-2 are “closed” by the intact fuses 178), while the tuning capacitor 143-3 is disconnected by the blown fuse 178 (i.e., the controllable connection 146-3 is made “open”). Fuses 178 may be selectively blown by applying an adequate voltage and/or current across the fuses 178 (e.g., by test probes or other appropriate equipment). In some embodiments, the fuses 178 may be discrete, surface-mount components, while in other embodiments, the fuses 178 may be wirebonds, solder bridges, or other materials that may be selectively broken (e.g., by the application of adequate voltage/current, as discussed above with reference to the filaments 154). As discussed above with reference to FIG. 11, the fuses 178 may be selectively blown in any desired manner to achieve a desired connectivity between the main capacitor 141 and the tuning capacitors 143, and thereby a desired capacitance.

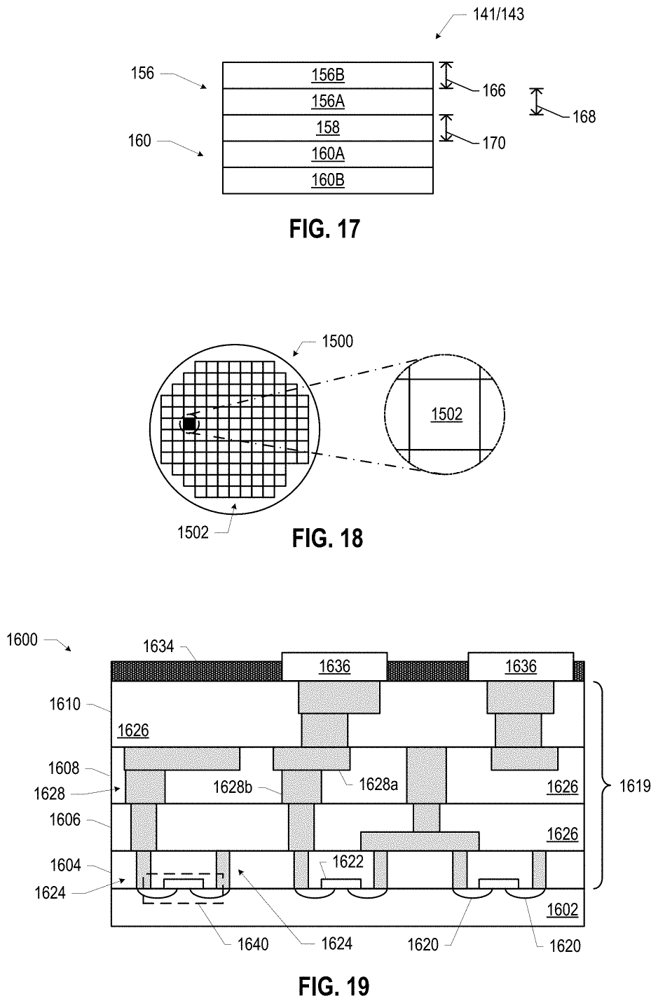

As noted above, any suitable materials may be used for the plates and capacitor dielectric of the main capacitor 141 and the tuning capacitors 143 in the tunable capacitor arrangements 110 disclosed herein. FIG. 17 is a side, cross-sectional view of an example capacitor 141/143, illustrating an example structure for any of the capacitors 141/143 disclosed herein. The capacitor 141/143 of FIG. 17 may include a first plate structure 156, a capacitor dielectric structure 158, and a second plate structure 160.

In some embodiments, the capacitor dielectric structure 158 may include a dielectric material with a relative dielectric constant between 20 and 120. In some such embodiments, the capacitor dielectric structure 158 may include tantalum and oxygen (e.g., in the form of tantalum oxide), zirconium and oxygen (e.g., in the form of zirconium oxide), hafnium and oxygen (e.g., in the form of hafnium oxide), or titanium and oxygen (e.g., in the form of titanium oxide). In some such embodiments, the thickness 170 of the capacitor dielectric structure 158 may be less than 100 nanometers. In some embodiments, the capacitor dielectric structure 158 may include an ultra-high-k material (e.g., a material having a dielectric constant greater than 120). In some such embodiments, the capacitor dielectric structure 158 may include barium, strontium, titanium, and oxygen (e.g., in the form of barium strontium titanate); or barium, titanium, and oxygen (e.g., in the form of barium titanate). A capacitor dielectric structure 158 may be fabricated using any suitable technique, such as deposition techniques for continuous films.

The first plate structure 156 may include a first region 156A and a second region 1568, with the first region 156A between the capacitor dielectric structure 158 and the second region 1568. In some embodiments, the first region 156A (in contact with the capacitor dielectric structure 158) may be selected to have a low leakage current in conjunction with the capacitor dielectric structure 158. In some embodiments, when the capacitor dielectric structure 158 includes a metallic element, the first region 156A may include that metallic element (e.g., when the capacitor dielectric structure 158 includes tantalum oxide, the first region 156A may be tantalum; when the capacitor dielectric structure 158 includes zirconium oxide, the first region 156A may be zirconium; when the capacitor dielectric structure 158 includes hafnium oxide, the first region 156A may be hafnium; or when the capacitor dielectric structure 158 includes titanium oxide, the first region 156A may be titanium). In some embodiments, the first region 156A may have a thickness 168 between 0.5 nanometers and 2 nanometers. The second region 1568 may be a metal having good band alignment and low leakage current in conjunction with the capacitor dielectric structure 158. In some embodiments, the second region 156B may include nickel, palladium, or copper. In some embodiments, the second region 156B may have a thickness 166 between 50 nanometers and 100 nanometers. In some embodiments, the first plate structure 156 may not include a first region 156A and a second region 156B with different material compositions, but may have a uniform material composition.

The second plate structure 160 may include a first region 160A and a second region 160B, with the first region 160A between the capacitor dielectric structure 158 and the second region 160B. The first region 160A may take any of the forms of the first region 156A discussed herein, and the second region 160B may take any of the forms of the second region 156B discussed herein. In some embodiments, the second plate structure 160 may not include a first region 160A and a second region 160B with different material compositions, but may have a uniform material composition. In one particular embodiment, a capacitor 141/143 may include a second region 160B of nickel, palladium, or copper; a first region 160A of titanium or titanium nitride; a capacitor dielectric structure 158 of titanium oxide; a first region 156A of titanium or titanium nitride; and a second region 156B of nickel, palladium, or copper. In some embodiments, the first plate structure 156, the capacitor dielectric structure 158, and the second plate structure 160 are deposited in-situ (e.g., in the same sputter deposition tool without breaking vacuum). The remainder of the package substrate 102 may be fabricated using conventional printed circuit board (PCB) technology (e.g., with copper interconnects having thicknesses between 2 microns and 50 microns).

For any of the tunable capacitor arrangements 110 disclosed herein, identifying which tuning operations are to be performed to achieve a desired total capacitance across the tunable capacitor arrangement 110 may be performed in any of a number of ways. In some embodiments, electrical characteristics (e.g., capacitances) of the main capacitor 141 and/or the tuning capacitors 143 may be measured (e.g., during test or validation) and appropriate tuning operations may then be performed (if any, in accordance with any of the embodiments disclosed herein) to bring the electrical characteristics of the tunable capacitor arrangement 110 closer to a target value.

In some embodiments, dimensional characteristics of the main capacitor 141 and/or the tuning capacitors 143 may be measured (e.g., the thickness of the capacitor dielectric structure 158, the thicknesses of the first plate structure 156 and/or the second plate structure 160, the lateral dimensions of the plate structures 156/158, etc.), and these dimensional characteristics may be used to estimate the electrical characteristics; the estimated electrical characteristics may then be used to select the appropriate tuning operations. For example, if the measured thickness 170 of the capacitor dielectric structure 158 is greater than the nominal thickness 170, the capacitances of the main capacitors 141 and the tuning capacitors 143 may be less than their nominal values, and tuning operations may be performed accordingly. Dimensional metrology may be performed by the manufacturer of the package substrate 102, or by another entity subsequent to the manufacture of the package substrate 102.

In some embodiments, the tuning operations may be performed during test operations using test equipment. For example, in the embodiment of FIG. 16, test probes may be brought into contact with the exposed portions of the second plate structure 160 during testing of the conductive contacts 132 at the face 140 of the package substrate 102, and electrical signals may be provided by the test probes to blow one or more of the fuses 178, as desired.

The IC packages 100 and tunable capacitor arrangements 110 disclosed herein may include, or may be included in, any suitable electronic component. FIGS. 18-22 illustrate various examples of apparatuses that may be included in any of the IC packages 100 disclosed herein, or may include any of the IC packages 100 disclosed herein.

FIG. 18 is a top view of a wafer 1500 and dies 1502 that may be included in an IC package 100, in accordance with various embodiments. For example, a die 1502 may be the IC die 104. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more transistors (e.g., some of the transistors 1640 of FIG. 19, discussed below) and/or supporting circuitry to route electrical signals to the transistors, as well as any other IC components. In some embodiments, the wafer 1500 or the die 1502 may include a PA, one or more resonators, one or more switches, one or more lasers, a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 21) or other logic that is configured to store information in the memory devices or execute instructions stored in the memory array.

FIG. 19 is a side, cross-sectional view of an IC device 1600 that may be included in an IC package 100, in accordance with various embodiments. For example, the IC device 1600 may be included in a die 1502 (e.g., in the IC die 104). One or more of the IC devices 1600 may be included in one or more dies 1502 (FIG. 18). The IC device 1600 may be formed on a substrate 1602 (e.g., the wafer 1500 of FIG. 18) and may be included in a die (e.g., the die 1502 of FIG. 18). The substrate 1602 may be a semiconductor substrate composed of semiconductor material systems including, for example, n-type or p-type materials systems (or a combination of both). The substrate 1602 may include, for example, a crystalline substrate formed using a bulk silicon or a silicon-on-insulator (SOI) substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 1502 of FIG. 18) or a wafer (e.g., the wafer 1500 of FIG. 18).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 19 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., the transistors 1640) of the device layer 1604 through one or more interconnect layers disposed on the device layer 1604 (illustrated in FIG. 19 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 19). Although a particular number of interconnect layers 1606-1610 is depicted in FIG. 19, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 19. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 19. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 may be formed above the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 19, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

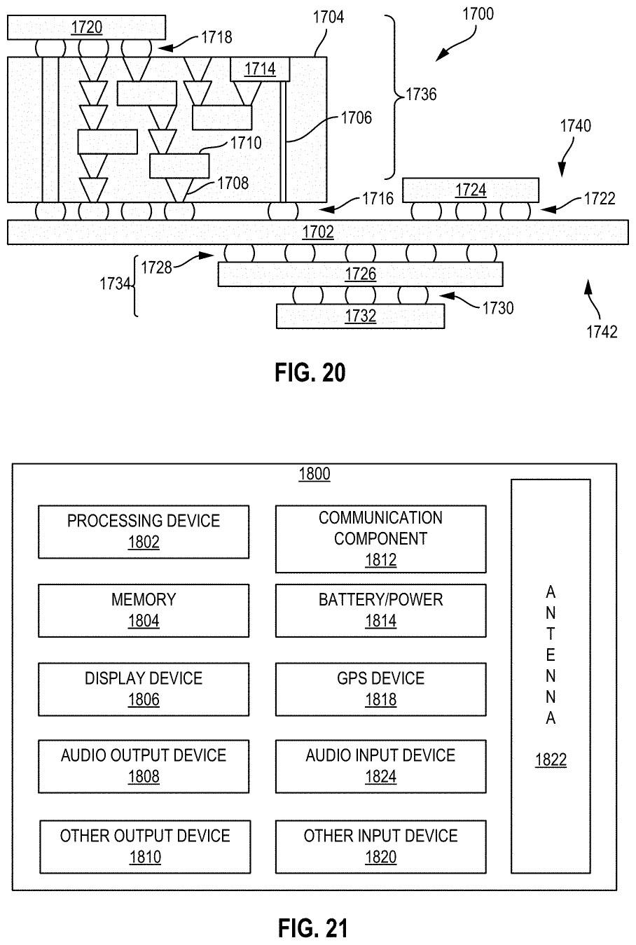

FIG. 20 is a side, cross-sectional view of an IC assembly 1700 that may include one or more IC packages 100, in accordance with various embodiments. For example, any of the IC packages included in the IC assembly 1700 may be an IC package 100 including any of the tunable capacitor arrangements 110 (or combination of tunable capacitor arrangements 110) disclosed herein. The IC assembly 1700 includes a number of components disposed on a circuit board 1702 (which may be, e.g., a motherboard). The IC assembly 1700 includes components disposed on a first face 1740 of the circuit board 1702 and an opposing second face 1742 of the circuit board 1702; generally, components may be disposed on one or both faces 1740 and 1742.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC assembly 1700 illustrated in FIG. 20 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 20), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 20, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 18), an IC device (e.g., the IC device 1600 of FIG. 19), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 20, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, PAs, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC assembly 1700 illustrated in FIG. 20 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 21 is a block diagram of an example electrical device 1800 that may include one or more IC packages 100 or vapor chambers, in accordance with various embodiments. For example, any suitable ones of the components of the electrical device 1800 may include one or more of the IC assemblies 150/1700, IC packages 100, tunable capacitor arrangements 110, IC devices 1600, or dies 1502 disclosed herein. A number of components are illustrated in FIG. 21 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 21, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication component 1812 (e.g., one or more communication components). For example, the communication component 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not. The communication component 1812 may include radio frequency (RF) components (e.g., power amplifiers and/or resonators) packaged in any of the IC packages 100 disclosed herein.

The communication component 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication component 1812 may manage wired communications, such as electrical, optical, or any other suitable communication protocols (e.g., the Ethernet). As noted above, the communication component 1812 may include multiple communication components. For instance, a first communication component 1812 may be dedicated to shorter-range wireless communications such as Wi-Fi or Bluetooth, and a second communication component 1812 may be dedicated to longer-range wireless communications such as global positioning system (GPS), EDGE, GPRS, CDMA, WiMAX, LTE, EV-DO, or others. In some embodiments, a first communication component 1812 may be dedicated to wireless communications, and a second communication component 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

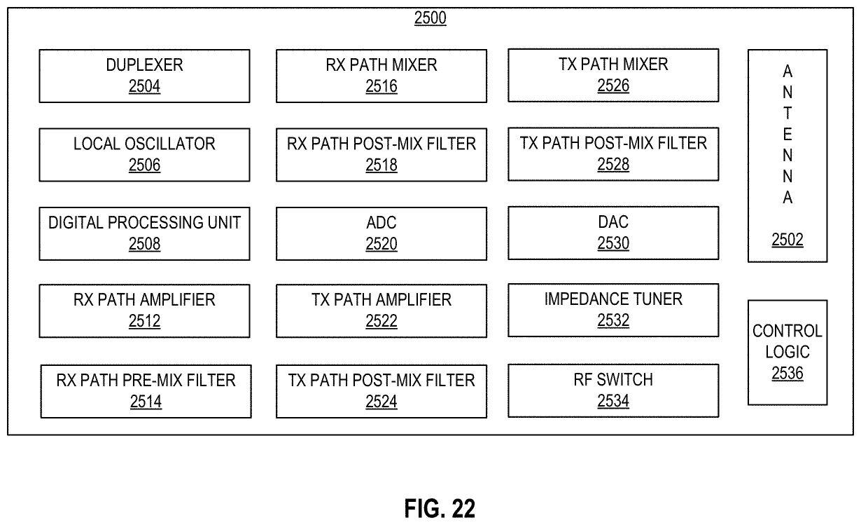

FIG. 22 is a block diagram of an example RF device 2500 that may include one or more IC packages 100, in accordance with any of the embodiments disclosed herein. For example, any suitable ones of the components of the RF device 2500 may include, or may be included in, an IC package 100 in accordance with any of the embodiments disclosed herein. Any of the components of the RF device 2500 may include, or be included in, an IC assembly 1700 as described with reference to FIG. 20. In some embodiments, the RF device 2500 may be included within any components of the computing device 1800 as described above with reference to FIG. 21 (e.g., the communication component 1812), or may be coupled to any of the components of the electrical device 1800 (e.g., may be coupled to the memory 1804 and/or to the processing device 1802 of the electrical device 1800). In still other embodiments, the RF device 2500 may further include any of the components described above with reference to FIG. 21, such as, but not limited to, the battery/power circuitry 1814, the memory 1804, and various input and output devices as discussed above with reference to FIG. 21.

In general, the RF device 2500 may be any device or system that may support wireless transmission and/or reception of signals in the form of electromagnetic waves in the RF range of approximately 3 kiloHertz (kHz) to 300 gigaHertz (GHz). In some embodiments, the RF device 2500 may be used for wireless communications, e.g., in a base station (BS) or a user equipment (UE) device of any suitable cellular wireless communications technology, such as GSM, WCDMA, or LTE. In a further example, the RF device 2500 may be used as, or in, a BS or a UE device of a millimeter-wave wireless technology such as fifth generation (5G) wireless (e.g., high-frequency/short wavelength spectrum, with frequencies in the range between about 20 GHz and 60 GHz, corresponding to wavelengths in the range between about 5 millimeters and 15 millimeters). In yet another example, the RF device 2500 may be used for wireless communications using Wi-Fi technology (e.g., a frequency band of 2.4 GHz, corresponding to a wavelength of about 12 cm, or a frequency band of 5.8 GHz, corresponding to a wavelength of about 5 cm). For example, the RF device 2500 may be included in a Wi-Fi-enabled device such as a desktop, a laptop, a video game console, a smart phone, a tablet, a smart TV, a digital audio player, a car, a printer, etc. In some implementations, a Wi-Fi-enabled device may be a node (e.g., a smart sensor) in a smart system configured to communicate data with other nodes. In another example, the RF device 2500 may be used for wireless communications using Bluetooth technology (e.g., a frequency band from about 2.4 GHz to about 2.485 GHz, corresponding to a wavelength of about 12 cm). In other embodiments, the RF device 2500 may be used for transmitting and/or receiving RF signals for purposes other than communication (e.g., in an automotive radar system, or in medical applications such as magnetic resonance imaging (MRI)).

In various embodiments, the RF device 2500 may be included in frequency-division duplex (FDD) or time-domain duplex (TDD) variants of frequency allocations that may be used in a cellular network. In an FDD system, the uplink (i.e., RF signals transmitted from the UE devices to a BS) and the downlink (i.e., RF signals transmitted from the BS to the US devices) may use separate frequency bands at the same time. In a TDD system, the uplink and the downlink may use the same frequencies but at different times.

A number of components are illustrated in FIG. 22 as included in the RF device 2500, but any one or more of these components may be omitted or duplicated, as suitable for the application. For example, in some embodiments, the RF device 2500 may be an RF device supporting both of wireless transmission and reception of RF signals (e.g., an RF transceiver), in which case it may include both the components of what is referred to herein as a transmit (TX) path and the components of what is referred to herein as a receive (RX) path. However, in other embodiments, the RF device 2500 may be an RF device supporting only wireless reception (e.g., an RF receiver), in which case it may include the components of the RX path, but not the components of the TX path; or the RF device 2500 may be an RF device supporting only wireless transmission (e.g., an RF transmitter), in which case it may include the components of the TX path, but not the components of the RX path.

In some embodiments, some or all of the components included in the RF device 2500 may be attached to one or more motherboards. In various embodiments, the RF device 2500 may not include one or more of the components illustrated in FIG. 22, but the RF device 2500 may include interface circuitry for coupling to the one or more components. For example, the RF device 2500 may not include an antenna 2502, but may include antenna interface circuitry (e.g., a matching circuitry, a connector and driver circuitry) to which an antenna 2502 may be coupled. In another set of examples, the RF device 2500 may not include a digital processing unit 2508 or a local oscillator 2506, but may include device interface circuitry (e.g., connectors and supporting circuitry) to which a digital processing unit 2508 or a local oscillator 2506 may be coupled.

As shown in FIG. 22, the RF device 2500 may include an antenna 2502, a duplexer 2504, a local oscillator 2506, and a digital processing unit 2508. As also shown in FIG. 22, the RF device 2500 may include an RX path that may include an RX path amplifier 2512 (which may include a PA and/or switches that may be included in the IC die 104), an RX path pre-mix filter 2514, a RX path mixer 2516, an RX path post-mix filter 2518, and an analog-to-digital converter (ADC) 2520. As further shown in FIG. 22, the RF device 2500 may include a TX path that may include a TX path amplifier 2522 (which may include a PA and/or switches that may be included in the IC die 104), a TX path post-mix filter 2524, a TX path mixer 2526, a TX path pre-mix filter 2528, and a digital-to-analog converter (DAC) 2530. Still further, the RF device 2500 may further include an impedance tuner 2532, an RF switch 2534 (which may include, or be included in, the IC die 104), and control logic 2536. In various embodiments, the RF device 2500 may include multiple instances of any of the components shown in FIG. 22. In some embodiments, the RX path amplifier 2512, the TX path amplifier 2522, the duplexer 2504, and the RF switch 2534 may be considered to form, or be a part of, an RF front-end (FE) of the RF device 2500. In some embodiments, the RX path amplifier 2512, the TX path amplifier 2522, the duplexer 2504, and the RF switch 2534 may be considered to form, or be a part of, an RF FE of the RF device 2500. In some embodiments, the RX path mixer 2516 and the TX path mixer 2526 (possibly with their associated pre-mix and post-mix filters shown in FIG. 22) may be considered to form, or be a part of, an RF transceiver of the RF device 2500 (or of an RF receiver or an RF transmitter if only RX path or TX path components, respectively, are included in the RF device 2500). In some embodiments, the RF device 2500 may further include one or more control logic elements/circuits, shown in FIG. 22 as control logic 2536 (providing, for example, an RF FE control interface). The control logic 2536 may be used to enhance control of complex RF system environment, support implementation of envelope tracking techniques, reduce dissipated power, etc.

The antenna 2502 may be configured to wirelessly transmit and/or receive RF signals in accordance with any wireless standards or protocols, e.g., Wi-Fi, LTE, or GSM, as well as any other wireless protocols that are designated as 3G, 4G, 5G, and beyond. If the RF device 2500 is an FDD transceiver, the antenna 2502 may be configured for concurrent reception and transmission of communication signals in separate, e.g., non-overlapping and non-continuous, bands of frequencies, e.g., in bands having a separation of, e.g., 20 MHz from one another. If the RF device 2500 is a TDD transceiver, the antenna 2502 may be configured for sequential reception and transmission of communication signals in bands of frequencies that may be the same, or overlapping for TX and RX paths. In some embodiments, the RF device 2500 may be a multi-band RF device, in which case the antenna 2502 may be configured for concurrent reception of signals having multiple RF components in separate frequency bands and/or configured for concurrent transmission of signals having multiple RF components in separate frequency bands. In such embodiments, the antenna 2502 may be a single wide-band antenna or a plurality of band-specific antennas (e.g., a plurality of antennas each configured to receive and/or transmit signals in a specific band of frequencies). In various embodiments, the antenna 2502 may include a plurality of antenna elements, e.g., a plurality of antenna elements forming a phased antenna array (i.e., a communication system or an array of antennas that may use a plurality of antenna elements and phase shifting to transmit and receive RF signals). Compared to a single-antenna system, a phased antenna array may offer advantages such as increased gain, ability of directional steering, and simultaneous communication. In some embodiments, the RF device 2500 may include more than one antenna 2502 to implement antenna diversity. In some such embodiments, the RF switch 2534 may be deployed to switch between different antennas.

An output of the antenna 2502 may be coupled to the input of the duplexer 2504. The duplexer 2504 may be any suitable component configured for filtering multiple signals to allow for bidirectional communication over a single path between the duplexer 2504 and the antenna 2502. The duplexer 2504 may be configured for providing RX signals to the RX path of the RF device 2500 and for receiving TX signals from the TX path of the RF device 2500.

The RF device 2500 may include one or more local oscillators 2506, configured to provide local oscillator signals that may be used for downconversion of the RF signals received by the antenna 2502 and/or upconversion of the signals to be transmitted by the antenna 2502.

The RF device 2500 may include the digital processing unit 2508, which may include one or more processing devices. In some embodiments, the digital processing unit 2508 may be implemented as the processing device 1802 of FIG. 21, descriptions of which are provided above. The digital processing unit 2508 may be configured to perform various functions related to digital processing of the RX and/or TX signals. Examples of such functions include, but are not limited to, decimation/downsampling, error correction, digital downconversion or upconversion, DC offset cancellation, automatic gain control, etc. Although not shown in FIG. 22, in some embodiments, the RF device 2500 may further include a memory device (e.g., the memory device 1804 described above with reference to FIG. 21) configured to cooperate with the digital processing unit 2508.

Turning to the details of the RX path that may be included in the RF device 2500, the RX path amplifier 2512 may include a low noise amplifier (LNA). An input of the RX path amplifier 2512 may be coupled to an antenna port (not shown) of the antenna 2502, e.g., via the duplexer 2504. The RX path amplifier 2512 may amplify the RF signals received by the antenna 2502.

An output of the RX path amplifier 2512 may be coupled to an input of the RX path pre-mix filter 2514, which may be a harmonic or band-pass (e.g., low-pass) filter, configured to filter received RF signals that have been amplified by the RX path amplifier 2512.

An output of the RX path pre-mix filter 2514 may be coupled to an input of the RX path mixer 2516, also referred to as a downconverter. The RX path mixer 2516 may include two inputs and one output. A first input may be configured to receive the RX signals, which may be current signals, indicative of the signals received by the antenna 2502 (e.g., the first input may receive the output of the RX path pre-mix filter 2514). A second input may be configured to receive local oscillator signals from one of the local oscillators 2506. The RX path mixer 2516 may then mix the signals received at its two inputs to generate a downconverted RX signal, provided at an output of the RX path mixer 2516. As used herein, downconversion refers to a process of mixing a received RF signal with a local oscillator signal to generate a signal of a lower frequency. In particular, the RX path mixer (e.g., downconverter) 2516 may be configured to generate the sum and/or the difference frequency at the output port when two input frequencies are provided at the two input ports. In some embodiments, the RF device 2500 may implement a direct-conversion receiver (DCR), also known as homodyne, synchrodyne, or zero-intermediate frequency (IF) receiver, in which case the RX path mixer 2516 may be configured to demodulate the incoming radio signals using local oscillator signals whose frequency is identical to, or very close to the carrier frequency of the radio signal. In other embodiments, the RF device 2500 may make use of downconversion to an IF. IFs may be used in superheterodyne radio receivers, in which a received RF signal is shifted to an IF, before the final detection of the information in the received signal is done. Conversion to an IF may be useful for several reasons. For example, when several stages of filters are used, they can all be set to a fixed frequency, which makes them easier to build and to tune. In some embodiments, the RX path mixer 2516 may include several such stages of IF conversion.

Although a single RX path mixer 2516 is shown in the RX path of FIG. 22, in some embodiments, the RX path mixer 2516 may be implemented as a quadrature downconverter, in which case it would include a first RX path mixer and a second RX path mixer. The first RX path mixer may be configured for performing downconversion to generate an in-phase (I) downconverted RX signal by mixing the RX signal received by the antenna 2502 and an in-phase component of the local oscillator signal provided by the local oscillator 2506. The second RX path mixer may be configured for performing downconversion to generate a quadrature (Q) downconverted RX signal by mixing the RX signal received by the antenna 2502 and a quadrature component of the local oscillator signal provided by the local oscillator 2506 (the quadrature component is a component that is offset, in phase, from the in-phase component of the local oscillator signal by 90 degrees). The output of the first RX path mixer may be provided to a I-signal path, and the output of the second RX path mixer may be provided to a Q-signal path, which may be substantially 90 degrees out of phase with the I-signal path.

The output of the RX path mixer 2516 may, optionally, be coupled to the RX path post-mix filter 2518, which may be low-pass filters. In case the RX path mixer 2516 is a quadrature mixer that implements the first and second mixers as described above, the in-phase and quadrature components provided at the outputs of the first and second mixers respectively may be coupled to respective individual first and second RX path post-mix filters included in the RX path post-mix filter 2518.

The ADC 2520 may be configured to convert the mixed RX signals from the RX path mixer 2516 from the analog to the digital domain. The ADC 2520 may be a quadrature ADC that, similar to the RX path mixer 2516, may include two ADCs, configured to digitize the downconverted RX path signals separated in in-phase and quadrature components. The output of the ADC 2520 may be provided to the digital processing unit 2508, configured to perform various functions related to digital processing of the RX signals so that information encoded in the RX signals can be extracted.

Turning to the details of the TX path that may be included in the RF device 2500, the digital signal to later be transmitted (TX signal) by the antenna 2502 may be provided, from the digital processing unit 2508, to the DAC 2530. Similar to the ADC 2520, the DAC 2530 may include two DACs, configured to convert, respectively, digital I- and Q-path TX signal components to analog form.

Optionally, the output of the DAC 2530 may be coupled to the TX path pre-mix filter 2528, which may be a band-pass (e.g., low-pass) filter (or a pair of band-pass, e.g., low-pass, filters, in case of quadrature processing) configured to filter out, from the analog TX signals output by the DAC 2530, the signal components outside of the desired band. The digital TX signals may then be provided to the TX path mixer 2526, which may also be referred to as an upconverter. Similar to the RX path mixer 2516, the TX path mixer 2526 may include a pair of TX path mixers, for in-phase and quadrature component mixing. Similar to the first and second RX path mixers that may be included in the RX path, each of the TX path mixers of the TX path mixer 2526 may include two inputs and one output. A first input may receive the TX signal components, converted to the analog form by the respective DAC 2530, which are to be upconverted to generate RF signals to be transmitted. The first TX path mixer may generate an in-phase (I) upconverted signal by mixing the TX signal component converted to analog form by the DAC 2530 with the in-phase component of the TX path local oscillator signal provided from the local oscillator 2506 (in various embodiments, the local oscillator 2506 may include a plurality of different local oscillators, or be configured to provide different local oscillator frequencies for the RX path mixer 2516 in the RX path and the TX path mixer 2526 in the TX path). The second TX path mixer may generate a quadrature phase (Q) upconverted signal by mixing the TX signal component converted to analog form by the DAC 2530 with the quadrature component of the TX path local oscillator signal. The output of the second TX path mixer may be added to the output of the first TX path mixer to create a real RF signal. A second input of each of the TX path mixers may be coupled the local oscillator 2506.

Optionally, the RF device 2500 may include the TX path post-mix filter 2524, configured to filter the output of the TX path mixer 2526.

As noted above, the TX path amplifier 2522 may be a PA (and may be, for example, included in the IC die 104), configured to amplify the upconverted RF signal before providing it to the antenna 2502 for transmission

In various embodiments, any of the RX path pre-mix filter 2514, the RX path post-mix filter 2518, the TX path post-mix filter 2524, and the TX path pre-mix filter 2528 may be implemented as RF filters. In some embodiments, each of such RF filters may include one or more resonators (e.g., AWRs, film bulk acoustic resonators (FBARs), Lamb wave resonators, and/or contour-wave resonators), arranged in any suitable manner (e.g., in a ladder configuration). Any of the RX path pre-mix filter 2514, the RX path post-mix filter 2518, the TX path post-mix filter 2524, and the TX path pre-mix filter 2528 may include one or more resonators. An individual resonator of an RF filter may include a layer of a piezoelectric material such as aluminum nitride, enclosed between a bottom electrode and a top electrode, with a cavity provided around a portion of each electrode in order to allow a portion of the piezoelectric material to vibrate during operation of the filter. Any such resonators may be included in an IC package 100 (e.g., in the IC die 104). In some embodiments, an RF filter may be implemented as a plurality of RF filters, or a filter bank. A filter bank may include a plurality of RF resonators that may be coupled to a switch (e.g., the RF switch 2534) configured to selectively switch any one of the plurality of RF resonators on and off (e.g., activate any one of the plurality of RF resonators), in order to achieve desired filtering characteristics of the filter bank (e.g., in order to program the filter bank). For example, such a filter bank may be used to switch between different RF frequency ranges when the RF device 2500 is, or is included in, a BS or in a UE device. In another example, such a filter bank may be programmable to suppress TX leakage on the different duplex distances.

The impedance tuner 2532 may include any suitable circuitry, configured to match the input and output impedances of the different RF circuitries to minimize signal losses in the RF device 2500. For example, the impedance tuner 2532 may include an antenna impedance tuner. Being able to tune the impedance of the antenna 2502 may be particularly advantageous because antenna's impedance is a function of the environment that the RF device 2500 is in, e.g., antenna's impedance changes depending on, e.g., if the antenna is held in a hand, placed on a car roof, etc.

As described above, the RF switch 2534 may be a device configured to route high-frequency signals through transmission paths in order to selectively switch between a plurality of instances of any one of the components shown in FIG. 22 (e.g., to achieve desired behavior and characteristics of the RF device 2500). The RF switch 2534 may be included in an IC die 104. In some embodiments, an RF switch 2534 may be used to switch between different antennas 2502. In other embodiments, an RF switch may be used to switch between a plurality of RF resonators (e.g., by selectively switching RF resonators on and off) of any of the filters included in the RF device 2500. Typically, an RF system may include a plurality of such RF switches.

The RF device 2500 provides a simplified version and, in further embodiments, other components not specifically shown in FIG. 22 may be included. For example, the RX path of the RF device 2500 may include a current-to-voltage amplifier between the RX path mixer 2516 and the ADC 2520, which may be configured to amplify and convert the downconverted signals to voltage signals. In another example, the RX path of the RF device 2500 may include a balun transformer for generating balanced signals. In yet another example, the RF device 2500 may further include a clock generator, which may include a suitable phase-lock loop (PLL), configured to receive a reference clock signal and use it to generate a different clock signal that may then be used for timing the operation of the ADC 2520, the DAC 2530, and/or that may also be used by the local oscillator 2506 to generate the local oscillator signals to be used in the RX path or the TX path.

The following paragraphs provide various examples of the embodiments disclosed herein.

Example 1 is an apparatus, including: an integrated circuit (IC) package substrate; and a tunable capacitor array in the package substrate.

Example 2 includes the subject matter of Example 1, and further specifies that the tunable capacitor array includes: a first embedded capacitor; a second embedded capacitor; and a controllable electrical connection between the first embedded capacitor and the second embedded capacitor.

Example 3 includes the subject matter of Example 2, and further specifies that the controllable electrical connection includes a fuse.

Example 4 includes the subject matter of any of Examples 2-3, and further specifies that the controllable electrical connection includes a filament in an air gap in the package substrate.

Example 5 includes the subject matter of Example 4, and further specifies that the air gap has a width between 50 microns and 250 microns.

Example 6 includes the subject matter of any of Examples 4-5, and further specifies that the filament has a width between 2 microns and 10 microns.

Example 7 includes the subject matter of any of Examples 4-6, and further specifies that the filament has a linear shape.

Example 8 includes the subject matter of any of Examples 4-6, and further specifies that the filament has a serpentine shape.

Example 9 includes the subject matter of any of Examples 2-8, and further specifies that, when the controllable electrical connection is in a closed state, the first embedded capacitor and the second embedded capacitor are connected in parallel.

Example 10 includes the subject matter of Example 9, and further specifies that, when the controllable electrical connection is in an open state, the first embedded capacitor and the second embedded capacitor are not connected in parallel.

Example 11 includes the subject matter of any of Examples 2-10, and further specifies that the controllable electrical connection is a first controllable electrical connection, and the tunable capacitor array further includes: a third embedded capacitor; and a second controllable electrical connection between the second embedded capacitor and the third embedded capacitor.

Example 12 includes the subject matter of Example 11, and further specifies that the second controllable electrical connection includes a fuse.

Example 13 includes the subject matter of any of Examples 11-12, and further specifies that the second controllable electrical connection includes a filament in an air gap in the package substrate.

Example 14 includes the subject matter of any of Examples 7-13, and further specifies that, when the second controllable electrical connection is in a closed state, the first embedded capacitor and the third embedded capacitor are connected in parallel.

Example 15 includes the subject matter of Example 14, and further specifies that, when the second controllable electrical connection is in an open state, the first embedded capacitor and the third embedded capacitor are not connected in parallel.

Example 16 includes the subject matter of any of Examples 1-15, and further specifies that the IC package substrate has a first face and an opposing second face, and the tunable capacitor array is spaced apart from the first face and from the second face.

Example 17 includes the subject matter of any of Examples 1-15, and further specifies that the IC package substrate has a first face and an opposing second face, and the tunable capacitor array is electrically exposed at the first face or the second face.

Example 18 includes the subject matter of Example 1, and further specifies that the tunable capacitor array includes: a plurality of embedded capacitors electrically exposed at a surface of the package substrate; and an arrangement of electrical connections between individual ones of the embedded capacitors such that some, but not all, of the embedded capacitors are connected in parallel.

Example 19 includes the subject matter of Example 18, and further specifies that the arrangement of electrical connections includes a conductive material at the face of the package substrate, and the conductive material contacts some, but not all, of the embedded capacitors.

Example 20 includes the subject matter of Example 19, and further specifies that the arrangement of electrical connections further includes a cut through the conductive material.

Example 21 includes the subject matter of Example 20, and further specifies that the cut extends into a dielectric material of the package substrate.

Example 22 includes the subject matter of any of Examples 20-21, and further specifies that the conductive material is a portion of a metal layer of the package substrate.

Example 23 includes the subject matter of any of Examples 19-21, and further specifies that the conductive material is in contact with an exposed metal layer of the package substrate.

Example 24 includes the subject matter of Example 23, and further specifies that the conductive material includes solder.

Example 25 includes the subject matter of any of Examples 18-24, and further specifies that the arrangement of electrical connections includes one or more zero-ohm resistors coupled to the surface of the package substrate.

Example 26 includes the subject matter of any of Examples 18-25, and further includes: a die coupled to the surface of the package substrate.

Example 27 includes the subject matter of any of Examples 18-25, and further includes: solder balls coupled to the surface of the package substrate.

Example 28 includes the subject matter of any of Examples 18-25, and further includes: a circuit board coupled to the surface of the package substrate.

Example 29 includes the subject matter of any of Examples 1-28, and further specifies that the tunable capacitor array includes a capacitor dielectric that is different from a dielectric material that separates metal layers in the package substrate.

Example 30 includes the subject matter of Example 29, and further specifies that the capacitor dielectric has a relative dielectric constant between 20 and 120.

Example 31 includes the subject matter of any of Examples 29-30, and further specifies that the capacitor dielectric includes tantalum and oxygen, zirconium and oxygen, hafnium and oxygen, or titanium and oxygen.

Example 32 includes the subject matter of any of Examples 30-31, and further specifies that the capacitor dielectric has a thickness that is less than 100 nanometers.

Example 33 includes the subject matter of Example 29, and further specifies that the capacitor dielectric includes: barium, strontium, titanium, and oxygen; or barium, titanium, and oxygen.

Example 34 includes the subject matter of any of Examples 29-33, and further specifies that a capacitor plate of the tunable capacitor array includes a first metal region and a second metal region, wherein the first metal region is between the capacitor dielectric and the second metal region, and the first metal region has a different material composition than the second metal region.

Example 35 includes the subject matter of Example 34, and further specifies that the first metal region has a thickness between 0.5 nanometers and 2 nanometers.

Example 36 includes the subject matter of any of Examples 34-35, and further specifies that the first metal region includes tantalum, zirconium, hafnium, or titanium.

Example 37 includes the subject matter of any of Examples 34-36, and further specifies that the second metal region includes copper, nickel, gold, platinum, or palladium.

Example 38 includes the subject matter of any of Examples 1-37, and further specifies that the apparatus is for radio frequency (RF) communication.

Example 39 is an integrated circuit (IC) package, including: an integrated circuit (IC) package substrate including a first embedded capacitor, a second embedded capacitor, and a fuse electrically coupled between the first embedded capacitor and the second embedded capacitor such that when the fuse is in a closed state, the first embedded capacitor and the second embedded capacitor are connected in parallel, and when the fuse is in an open state, the first embedded capacitor and the second embedded capacitor are not connected in parallel; and a die coupled to the package substrate.

Example 40 includes the subject matter of Example 39, and further specifies that the fuse includes a filament in an air gap in the package substrate.

Example 41 includes the subject matter of Example 40, and further specifies that the air gap has a width between 50 microns and 250 microns.

Example 42 includes the subject matter of any of Examples 40-41, and further specifies that the filament has a width between 2 microns and 10 microns.

Example 43 includes the subject matter of any of Examples 40-42, and further specifies that the filament has a linear shape.

Example 44 includes the subject matter of any of Examples 40-42, and further specifies that the filament has a serpentine shape.

Example 45 includes the subject matter of any of Examples 39-44, and further specifies that the fuse is a first fuse, and the package substrate further includes: a third embedded capacitor; and a second fuse electrically coupled between the second embedded capacitor and the third embedded capacitor such that when the second fuse is in a closed state, the first embedded capacitor and the third embedded capacitor are connected in parallel, and when the second fuse is in an open state, the first embedded capacitor and the third embedded capacitor are not connected in parallel.

Example 46 includes the subject matter of Example 45, and further specifies that the second controllable electrical connection includes a filament in an air gap in the package substrate.

Example 47 includes the subject matter of any of Examples 39-46, and further specifies that the fuse is in an open state.

Example 48 includes the subject matter of any of Examples 39-46, and further specifies that the fuse is in a closed state.

Example 49 includes the subject matter of any of Examples 39-48, and further specifies that the IC package substrate has a first face and an opposing second face, and the tunable capacitor array is spaced apart from the first face and from the second face.

Example 50 includes the subject matter of any of Examples 39-49, and further specifies that the die includes a power amplifier.

Example 51 includes the subject matter of any of Examples 39-50, and further specifies that the tunable capacitor array includes a capacitor dielectric that is different from a dielectric material that separates metal layers in the package substrate.

Example 52 includes the subject matter of Example 51, and further specifies that the capacitor dielectric has a relative dielectric constant between 20 and 120.

Example 53 includes the subject matter of any of Examples 51-52, and further specifies that the capacitor dielectric includes tantalum and oxygen, zirconium and oxygen, hafnium and oxygen, or titanium and oxygen.

Example 54 includes the subject matter of any of Examples 52-53, and further specifies that the capacitor dielectric has a thickness that is less than 100 nanometers.

Example 55 includes the subject matter of Example 51, and further specifies that the capacitor dielectric includes: barium, strontium, titanium, and oxygen; or barium, titanium, and oxygen.

Example 56 includes the subject matter of any of Examples 51-55, and further specifies that a capacitor plate of the first embedded capacitor includes a first metal region and a second metal region, wherein the first metal region is between the capacitor dielectric and the second metal region, and the first metal region has a different material composition than the second metal region.

Example 57 includes the subject matter of Example 56, and further specifies that the first metal region has a thickness between 0.5 nanometers and 2 nanometers.

Example 58 includes the subject matter of any of Examples 56-57, and further specifies that the first metal region includes tantalum, zirconium, hafnium, or titanium.

Example 59 includes the subject matter of any of Examples 56-57, and further specifies that the second metal region includes copper, nickel, gold, platinum, or palladium.

Example 60 includes the subject matter of any of Examples 39-59, and further specifies that the die is part of a radio frequency (RF) communication system.

Example 61 is an integrated circuit (IC) package, including: a package substrate including a plurality of embedded capacitors electrically exposed at a face of the package substrate; and an IC die coupled to the package substrate.

Example 62 includes the subject matter of Example 61, and further specifies that the face of the package substrate is a first face of the package substrate, the package substrate has a second, opposing face, and the IC die is coupled to the first face.

Example 63 includes the subject matter of Example 61, and further specifies that the face of the package substrate is a first face of the package substrate, the package substrate has a second, opposing face, and the IC die is coupled to the second face.

Example 64 includes the subject matter of any of Examples 61-63, and further includes: an arrangement of electrical connections between individual ones of the embedded capacitors such that some, but not all, of the embedded capacitors are connected in parallel.

Example 65 includes the subject matter of Example 64, and further specifies that the arrangement of electrical connections includes a conductive material at the face of the package substrate, and the conductive material contacts some, but not all, of the embedded capacitors.

Example 66 includes the subject matter of Example 65, and further specifies that the arrangement of electrical connections further includes a cut through the conductive material.

Example 67 includes the subject matter of Example 66, and further specifies that the cut extends into a dielectric material of the package substrate.

Example 68 includes the subject matter of any of Examples 66-67, and further specifies that the conductive material is a portion of a metal layer of the package substrate.

Example 69 includes the subject matter of any of Examples 65-67, and further specifies that the conductive material is in contact with an exposed metal layer of the package substrate.

Example 70 includes the subject matter of Example 69, and further specifies that the conductive material includes solder.

Example 71 includes the subject matter of any of Examples 64-70, and further specifies that the arrangement of electrical connections includes one or more zero-ohm resistors coupled to the face of the package substrate.

Example 72 includes the subject matter of any of Examples 61-71, and further specifies that an individual embedded capacitor includes a capacitor dielectric that is different from a dielectric material that separates metal layers in the package substrate.

Example 73 includes the subject matter of Example 72, and further specifies that the capacitor dielectric has a relative dielectric constant between 20 and 120.

Example 74 includes the subject matter of any of Examples 72-73, and further specifies that the capacitor dielectric includes tantalum and oxygen, zirconium and oxygen, hafnium and oxygen, or titanium and oxygen.

Example 75 includes the subject matter of any of Examples 73-74, and further specifies that the capacitor dielectric has a thickness that is less than 100 nanometers.

Example 76 includes the subject matter of Example 72, and further specifies that the capacitor dielectric includes: barium, strontium, titanium, and oxygen; or barium, titanium, and oxygen.

Example 77 includes the subject matter of any of Examples 72-76, and further specifies that a capacitor plate of the individual embedded capacitor includes a first metal region and a second metal region, wherein the first metal region is between the capacitor dielectric and the second metal region, and the first metal region has a different material composition than the second metal region.

Example 78 includes the subject matter of Example 77, and further specifies that the first metal region has a thickness between 0.5 nanometers and 2 nanometers.

Example 79 includes the subject matter of any of Examples 77-78, and further specifies that the first metal region includes tantalum, zirconium, hafnium, or titanium.

Example 80 includes the subject matter of any of Examples 77-79, and further specifies that the second metal region includes copper, nickel, gold, platinum, or palladium.

Example 81 includes the subject matter of any of Examples 61-80, and further specifies that the die is part of a radio frequency (RF) communication system.

Example 82 includes the subject matter of any of Examples 61-81, and further specifies that the die includes a power amplifier or a resonator.

Example 83 is a method of tuning a capacitor array in a package substrate, including: making electrical contact with conductive contacts at a surface of a package substrate; and applying an electrical signal across the conductive contacts to cause a change in the arrangement of electrical connections among the capacitor array.

Example 84 includes the subject matter of Example 83, and further specifies that applying the electrical signal includes supplying a current to cause a fuse to go from a closed state to an open state.

Example 85 includes the subject matter of Example 84, and further specifies that the fuse includes a filament in an air gap embedded in the package substrate.

Example 86 includes the subject matter of Example 84, and further specifies that the fuse includes a wirebond across the conductive contacts.

Example 87 includes the subject matter of Example 83, and further specifies that making electrical contact includes bringing test probes into contact with the conductive contacts.

Example 88 includes the subject matter of Example 87, and further specifies that applying the electrical signal includes applying the electrical signal during a test process.

1. An apparatus, comprising:
an integrated circuit (IC) package substrate; and
a tunable capacitor array in the package substrate, wherein the tunable capacitor array includes a plurality of embedded capacitors, the tunable capacitor array includes a capacitor dielectric that is different from a dielectric material that separates metal layers in the package substrate, a capacitor plate of the tunable capacitor array includes a first metal region and a second metal region, the first metal region is between the capacitor dielectric and the second metal region, and the first metal region has a different material composition than the second metal region.

2. The apparatus of claim 1, wherein the tunable capacitor array includes:
a first embedded capacitor;
a second embedded capacitor; and
a controllable electrical connection between the first embedded capacitor and the second embedded capacitor.

3. The apparatus of claim 2, wherein the controllable electrical connection includes a filament in an air gap in the package substrate.

4. The apparatus of claim 3, wherein the filament has a linear shape.

5. The apparatus of claim 3, wherein the filament has a serpentine shape.

6. The apparatus of claim 2, wherein the controllable electrical connection is a first controllable electrical connection, and the tunable capacitor array further includes:
a third embedded capacitor; and
a second controllable electrical connection between the second embedded capacitor and the third embedded capacitor.

7. (canceled)

8. An integrated circuit (IC) package, comprising:
an integrated circuit (IC) package substrate including a first embedded capacitor, a second embedded capacitor, and a fuse electrically coupled between the first embedded capacitor and the second embedded capacitor such that when the fuse is in a closed state, the first embedded capacitor and the second embedded capacitor are connected in parallel, and when the fuse is in an open state, the first embedded capacitor and the second embedded capacitor are not connected in parallel; and
a die coupled to the package substrate;
wherein the first embedded capacitor includes a capacitor dielectric that is different from a dielectric material that separates metal layers in the IC package substrate, and the capacitor dielectric has a relative dielectric constant between 20 and 120.

9. The IC package of claim 8, wherein the fuse is a first fuse, and the package substrate further includes:
a third embedded capacitor; and
a second fuse electrically coupled between the second embedded capacitor and the third embedded capacitor such that when the second fuse is in a closed state, the first embedded capacitor and the third embedded capacitor are connected in parallel, and when the second fuse is in an open state, the first embedded capacitor and the third embedded capacitor are not connected in parallel.

10. The IC package of claim 8, wherein the die includes a power amplifier.

11. The IC package of claim 8, wherein the die is part of a radio frequency (RF) communication system.

12. An integrated circuit (IC) package, comprising:
a package substrate including a plurality of embedded capacitors electrically exposed at a face of the package substrate, wherein the arrangement of electrical connections includes one or more zero-ohm resistors coupled to the face of the package substrate, and the zero-ohm resistors are surface-mounted discrete components or wirebonded components; and
an IC die coupled to the package substrate.

13. The IC package of claim 12, further comprising:
an arrangement of electrical connections between individual ones of the embedded capacitors such that some, but not all, of the embedded capacitors are connected in parallel.

14. The IC package of claim 13, wherein the arrangement of electrical connections includes a conductive material at the face of the package substrate, and the conductive material contacts some, but not all, of the embedded capacitors.

15. The IC package of claim 14, wherein the arrangement of electrical connections further includes a cut through the conductive material.

16. The IC package of claim 15, wherein the cut extends into a dielectric material of the package substrate.

17. The IC package of claim 15, wherein the conductive material is a portion of a metal layer of the package substrate.

18-20. (canceled)

21. The apparatus of claim 1, wherein the first metal region includes tantalum, zirconium, hafnium, or titanium.

22. The apparatus of claim 1, wherein the second metal region includes copper, nickel, gold, platinum, or palladium.

23. The IC package of claim 8, wherein the capacitor dielectric includes tantalum and oxygen, zirconium and oxygen, hafnium and oxygen, or titanium and oxygen.

24. The IC package of claim 8, wherein the capacitor dielectric includes:
barium, strontium, titanium, and oxygen; or
barium, titanium, and oxygen.
